(19) United States
(12) Patent Application Publication
(10) Pub. No.: US 2024/0038872 A1
(43) Pub. Date: Feb. 1, 2024

(54) GATE PROFILE TUNING FOR MULTIGATE DEVICE

(71) Applicant: Taiwan Semiconductor Manufacturing Company, Ltd., Hsin-Chu (TW)

(72) Inventors: Cheng-I Lin, Hsinchu (TW); Hao-Ming Tang, Taipei City (TW); Shu-Han Chen, Hsinchu City (TW); Chi On Chui, Hsinchu City (TW)

(21) Appl. No.: 18/153,700

(22) Filed: Jan. 12, 2023

Related U.S. Application Data
(60) Provisional application No. 63/393,079, filed on Jul. 28, 2022.
(60) Provisional application No. 63/387,001, filed on Dec. 12, 2022.

(51) Int. Cl. H01L 29/66; H01L 21/8234; H01L 29/786; H01L 29/423

(52) U.S. Cl. CPC H01L 29/66545; H01L 21/823412; H01L 21/823468; H01L 29/78696; H01L 29/42392; H01L 29/6656

(57) ABSTRACT

Gate profile tuning techniques are disclosed herein. An exemplary gate profile tuning method includes forming a gate structure over a channel layer. The gate structure includes a dummy gate and gate spacers disposed along sidewalls of the dummy gate. The method further includes partially removing the dummy gate to form a gate opening that defines a gate profile. The gate profile is then modified by treating portions of the gate spacers (for example, by oxygen plasma treatment) and removing the treated portions of the gate spacers (for example, by oxide removal). After removing a remainder of the dummy gate to expose the channel layer, a gate stack of the gate structure is formed in the gate opening. The gate stack has a funnel-shaped profile. In some embodiments, a width of the gate stack above the channel layer is greater than a width of the gate stack below the channel layer.

This is a non-provisional application of and claims benefit of U.S. Provisional Patent Application Ser. No. 63/393,079, filed Jul. 28, 2022, and U.S. Provisional Patent Application Ser. No. 63/387,001, filed Dec. 12, 2022, the entire disclosures of which are incorporated herein by reference.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, gate replacement processes, which typically involve replacing polysilicon gate electrodes with metal gate electrodes, have been implemented to improve device performance, where work function values of the metal gate electrodes can be tuned during the gate replacement processes to provide devices having different threshold (operating) voltages. Although existing gate fabrication techniques and/or gate replacement processes have been generally adequate for their intended purposes, they have not been entirely satisfactory in all respects as IC technologies and/or IC feature dimensions shrink.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a fragmentary perspective view of a multigate device, in portion or entirety, according to various aspects of the present disclosure.

FIG. 1B is a fragmentary cross-sectional view of the multigate device, in portion or entirety, along line B-B of FIG. 1A according to various aspects of the present disclosure.

FIG. 2 is a flow chart of a method for fabricating a device having a gate structure with an improved profile according to various aspects of the present disclosure.

FIGS. 3A-9A, FIGS. 3B-9B, and FIGS. 3C-9C are various views of a device, in portion or entirety, at various fabrication stages associated with the method of FIG. 2 according to various aspects of the present disclosure.

FIG. 10 provides an exemplary plot, in portion or entirety, that illustrates effects of process pressure on reactive species of an oxygen-containing plasma according to various aspects of the present disclosure.

FIG. 11 and FIG. 12 illustrate fragmentary cross-sectional views of a device, in portion or entirety, at various fabrication stages using different gate profile modification sequences according to various aspects of the present disclosure.

FIGS. 13A-19A, FIGS. 13B-19B, and FIGS. 13C-19C are various views of another device, in portion or entirety, at various fabrication stages associated with the method of FIG. 2 according to various aspects of the present disclosure.

FIGS. 20A-20D are fragmentary cross-sectional views of a device, in portion or entirety, at various fabrication stages when an upper half of gate spacers are exposed for gate profile modification according to various aspects of the present disclosure.

FIGS. 21A-21D are fragmentary cross-sectional views of a device, in portion or entirety, at various fabrication stages when an upper fourth of gate spacers are exposed for gate profile modification according to various aspects of the present disclosure.

### DETAILED DESCRIPTION

The present disclosure relates generally to integrated circuit (IC) devices and/or semiconductor devices, and more particularly, to gate structures of multigate devices and methods of fabricating gate structures of multigate devices.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

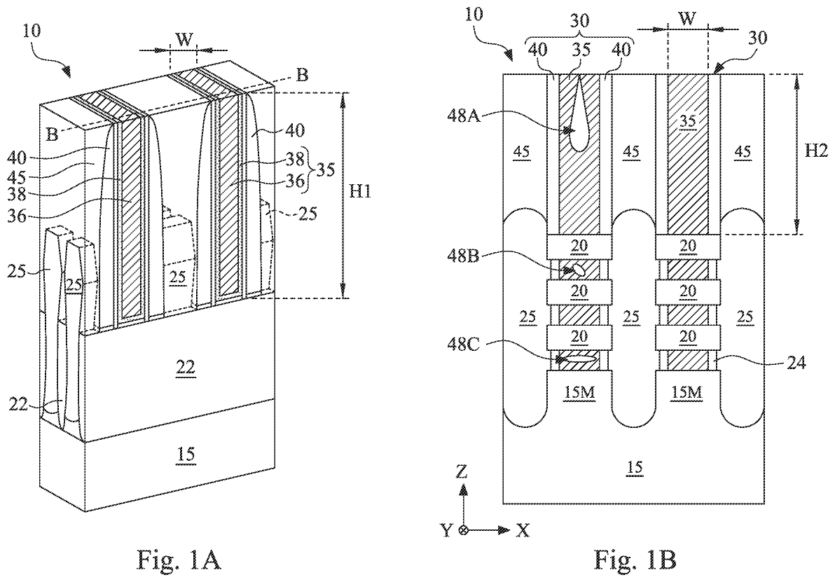

For advanced IC technology nodes, non-planar transistors, such as fin-like field effect transistors (FinFETs) and gate-all-around (GAA) transistors (collectively referred to as multigate devices), have become a popular and promising candidate for high performance and low leakage applications. FIG. 1A is a fragmentary perspective view of an exemplary multigate device 10, in portion or entirety, according to various aspects of the present disclosure, and FIG. 1B is a fragmentary cross-sectional view of multigate device 10, in portion or entirety, along line B-B of FIG. 1A according to various aspects of the present disclosure. Multigate device 10 is a GAA transistor that includes a substrate 15, substrate mesas 15M extending from substrate 15, channel layers 20 suspended over substrate 15, isolation features 22, inner spacers 24, source/drains 25, gate structures 30 having gate stacks 35 (e.g., gate electrodes 36 and gate dielectrics 38) and gate spacers 40 disposed along sidewalls of gate stacks 35, and a dielectric layer 45. Channel layers extend between respective source/drains 25 along the x-direction, and inner spacers 24 are between gate stacks 35 and source/drains 25. Gate structures 30 are disposed over respective channel layers 20 and between respective source/drains 25. In the X-Z plane, gate stacks 35 are over respective top channel layers 20, between respective channel layers 20, and between respective channel layers 20 and respective substrate mesas 15M. In the Y-Z plane, gate stacks at least partially surround (e.g., wrap and/or encircle) respective channel layers 20. During operation of the GAA transistor, current can flow through channel layers 20 and between source/drains 25. Gate stacks 35 has a width W (critical dimension CD) between gate spacers a height H1 between tops of gate stacks 35 and isolation feature 22, and a height H2 between the tops of gate stacks 35 and top channel layers 20. FIG. 1A and FIG. 1B have been simplified for the sake of clarity to better understand the inventive concepts of the present disclosure. Additional features can be added in multigate device 10, and some of the features described below can be replaced, modified, or eliminated in other embodiments of multigate device 10.

Gate stacks 35 can be fabricated using a gate replacement process, which typically involves replacing a dummy gate (e.g., a polysilicon gate) of a gate structure with a gate stack (e.g., a metal gate). An exemplary gate replacement process can include removing a dummy gate of a respective gate structure 30 to form a gate opening having sidewalls formed by gate spacers 40, forming gate dielectric 38 (e.g., an interfacial layer and a high-k dielectric layer) in and partially filling the gate opening, and forming gate electrode 36 over gate dielectric 38 to fill a remainder of the gate opening (e.g., a work function layer, a metal fill layer, etc.). Gate dielectric 38 and gate electrode 36 combine to form gate stack 35. A planarization process may be performed after depositing gate dielectric 38 and/or depositing gate electrode 36.

As IC feature sizes shrink with advanced IC technology nodes, dimensions of multigate devices, such as multigate device 10, are correspondingly decreasing, which has led to gate openings having significantly smaller widths and/or higher aspect ratios. Gate replacement processes that involve forming gate stacks in narrower gate openings and/or gate openings having higher aspect ratios (e.g., higher ratios of height H1 to width W and/or higher ratios of height H2 to width W) are more susceptible to voids and/or seams forming in the gate stacks. For example, during a gate replacement process, conductive material, such as various metal layers, deposited in a gate opening may fill or close (pinch) off a top of the gate opening before completely filling the gate opening. This can cause voids and/or seams to form in the conductive material of the gate stack. This phenomenon is illustrated in FIG. 1B, where one of gate stacks includes voids/seams 48A-48C (e.g., air gaps) that may significantly degrade the GAA transistor's performance (e.g., increase gate resistance and/or RC delay) and/or device yield (e.g., the GAA transistor is discarded if the GAA transistor has too many defects (i.e., voids/seams)). Void/seam formation is particularly likely when the gate opening has a high aspect ratio, such as when a width of the gate opening (which corresponds with width W) is substantially less than a depth of the gate opening (which corresponds with height H2 and/or height H2) (e.g., a ratio of depth to width of gate opening is greater than about 4).

The present disclosure addresses such challenges by tuning and/or modifying a gate profile of a top portion of a gate opening during a gate replacement process in a manner that improves a gate stack fill process window. For example, at certain gate heights, a width of a gate opening (and thus subsequently formed gate stack) is enlarged to reduce an aspect ratio of the gate opening, which can improve gap fill and reduce void/seam formation in the gate stack. In some embodiments, the disclosed gate profile tuning techniques include partially removing a dummy gate to form a gate opening, modifying a profile of the gate opening by treating exposed portions of the gate spacers and removing the treated portions of the gate spacers, removing a remainder of the dummy gate, and filling the gate opening with a gate stack (e.g., a gate dielectric and a gate electrode). The treating is tuned to taper sidewalls of, at least, an upper portion of the gate opening, such as a portion of the gate opening above a channel layer. In some embodiments, the modified profile of the gate opening is funnel shaped. In some embodiments, treating the exposed portions of the gate spacers includes performing an ion-dominated oxidation, a radical-dominated oxidation, or combinations thereof. Parameters of a gate spacer treatment process can be tuned to control composition changes of the gate spacers (e.g., oxidation thereof) and thus control tapering thereof. Targeting upper portions of the gate openings/gate spacers for width enlargement can reduce and/or eliminate pinch off that can cause void/seam formation in the gate stack. In some embodiments, the disclosed gate profile tuning techniques can increase a width of a gate opening to increase a width of a gate stack, such as from a width less than a desired width (e.g., critical dimension (CD)) to a width that is about the same as the desired width. Details of improved gate structures and/or gate opening profiles and methods of design and/or fabrication thereof are described herein in the following pages.

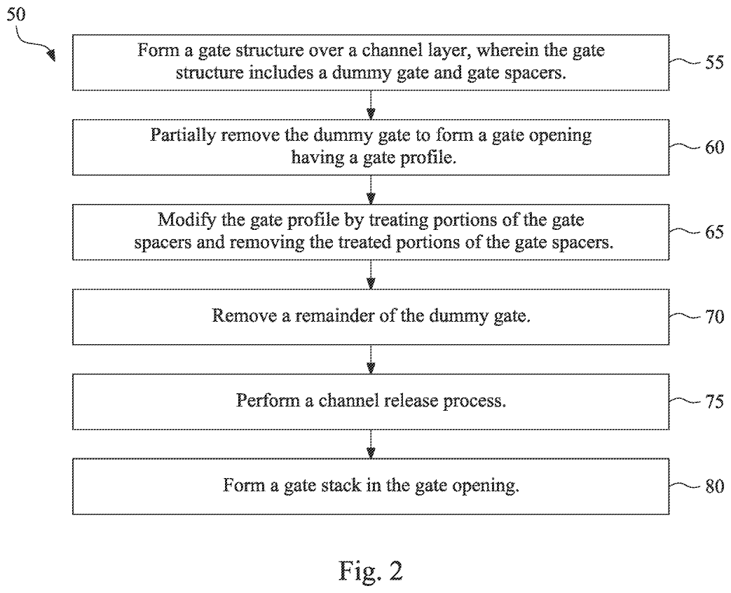

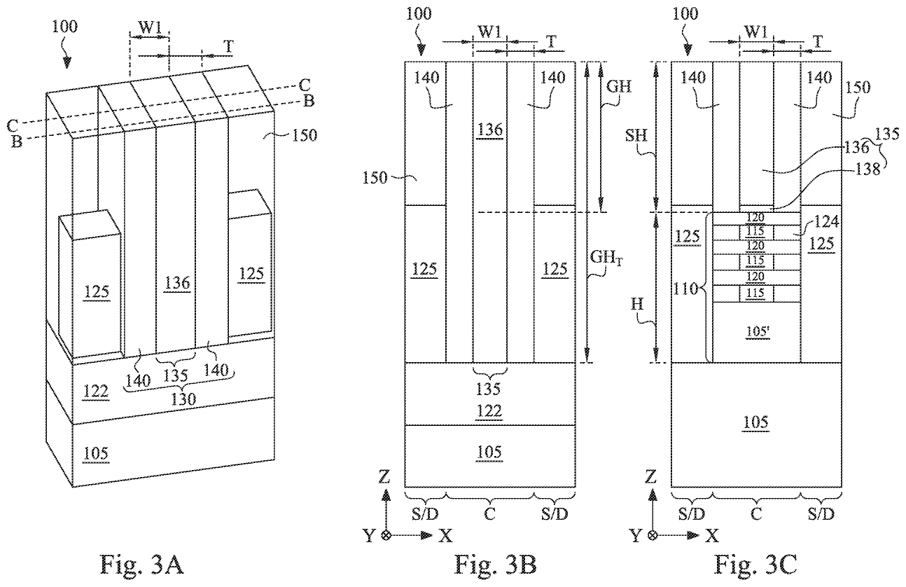

FIG. 2 is a flow chart of a method 50 for fabricating a device having a gate structure with an improved profile (e.g., minimal to no voids and/or seams and/or having desired critical dimension) according to various aspects of the present disclosure. FIGS. 3A-9A, FIGS. 3B-9B, and FIGS. 3C-9C are various views of a device 100, in portion or entirety, at various fabrication stages associated with method 50 in FIG. 2 according to various aspects of the present disclosure. FIGS. 3A-9A are fragmentary perspective views of device 100. FIGS. 3B-9B are fragmentary cross-sectional views of device 100 taken along lines B-B of FIGS. 3A-9A, respectively. FIGS. 3C-9C are fragmentary cross-sectional views of device 100 taken along lines C-C of FIGS. 3A-9A, respectively. FIG. 2, FIGS. 3A-9A, FIGS. 3B-9B, and FIGS. 3C-9C are discussed concurrently herein for ease of description and understanding. The cross-sectional views of FIGS. 3B-9B and FIGS. 3C-9C are obtained by “cutting” device 100 along the x-direction shown in FIGS. 3A-9A, and thus, the cross-sectional views in FIGS. 3B-9B and FIGS. 3C-9C may be referred to as x-cut views. The x-cut views are taken through a portion of device 100 that includes a channel region disposed between source/drain regions and where a gate structure is disposed over the channel region, instead of a portion of device 100 where the gate structure wraps the channel region (i.e., the x-cut views are through the X-Z plane instead of the Y-Z plane of a multigate device). FIG. 2, FIGS. 3A-9A, FIGS. 3B-9B, and FIGS. 3C-9C have been simplified for the sake of clarity to better understand the inventive concepts of the present disclosure. Additional steps can be provided before, during, and after method 50, and some of the steps described can be moved, replaced, or eliminated for additional embodiments of method 50. Additional features can be added in device 100, and some of the features described below can be replaced, modified, or eliminated in other embodiments of device 100.

Turning to FIG. 2 and FIGS. 3A-3C, method 50 includes forming a gate structure over a channel layer, where the gate structure includes a dummy gate and gate spacers. This process can begin with receiving and/or forming a multigate device precursor that includes a substrate (wafer) 105, a channel layer 110 (depicted as having a fin portion 105′ (i.e., a patterned, projecting portion of substrate 105), semiconductor layers 115, and semiconductor layers 120), an isolation feature 122, inner spacers 124, epitaxial source/drains 125, a gate structure 130 (depicted as having a dummy gate 135 and gate spacers 140), and a dielectric layer 150. Channel layer 110 is in a channel region C of device 100, and epitaxial source/drains 125 are in source/drain regions S/D of device 100. Semiconductor layers 120 and fin portion 105′ of channel layer 100 extend between epitaxial source/drains 125 along the x-direction, and inner spacers 124 are between semiconductor layers 115 and epitaxial source/drains 125. Gate structure 130 is disposed over channel layer 110 and between epitaxial source/drains 125. In the X-Z plane, gate structure 130 is on a top of channel layer 110, and in the Y-Z plane, gate structure 130 is on a top and sides of channel layer 110. For example, gate structure 130 wraps channel layer 110 in the Y-Z plane. Gate structure 130 has a total gate height GH_{T}, which is between a top surface of isolation feature 122 and a top surface of gate structure 130, and a gate height GH above channel layer 110, which is between a top surface of channel layer 110 (here, top surface of topmost semiconductor layer 120) and top surface of gate structure 130.

Substrate 105 includes an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlinAs, AlGaAs, GalnAs, GaInP, GaInAsP, or combinations thereof; or combinations thereof. In the depicted embodiment, substrate 105 is a silicon substrate. In some embodiments, substrate 105 is a semiconductor-on-insulator substrate, such as a silicon-on-insulator (all) substrate, a silicon germanium-on-insulator (SGOI) substrate, or a germanium-on-insulator (GOI) substrate. Substrate 105 (including fin portion 105′) can include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, other p-type dopant, or combinations thereof. In some embodiments, the doped regions include a combination of p-type dopants and n-type dopants. The doped regions can be formed directly on and/or in substrate 105, for example, providing a p-well structure, an n-well structure, a dual-well structure, a raised structure, other suitable structure, or combinations thereof. In some embodiments, substrate 105, fin portion 105′, and semiconductor layers thereover can include a p-well, such as where device 100 is an n-type transistor, or an n-well, such as where device 100 is a p-type transistor.

Channel layer 110 extends along the x-direction, having a length along the x-direction, a width along a y-direction, and a height H along a z-direction. Semiconductor layers 115 and semiconductor layers 120 are stacked vertically (e.g., along the z-direction) in an interleaving and/or alternating configuration from a top surface of substrate 105. A composition of semiconductor layers 115 is different than a composition of semiconductor layers 120 to achieve etching selectivity and/or different oxidation rates during subsequent processing. Semiconductor layers 115 and semiconductor layers 120 include different materials, constituent atomic percentages, constituent weight percentages, thicknesses, characteristics, or combinations thereof to achieve desired etching selectivity during an etching process, such as an etch process implemented to form suspended channel layers in channel region C. For example, semiconductor layers 115 include silicon germanium, semiconductor layers 120 include silicon, and a silicon etch rate of semiconductor layers 120 is different than a silicon germanium etch rate of semiconductor layers 115 to a given etchant. In some embodiments, semiconductor layers 115 and semiconductor layers 120 include the same material but different constituent atomic percentages to achieve etching selectivity. For example, semiconductor layers 115 and semiconductor layers 120 include silicon germanium with different silicon atomic percentages and/or different germanium atomic percentages. The present disclosure contemplates semiconductor layers 115 and semiconductor layers 120 including any combination of semiconductor materials that provides desired etching selectivity, desired oxidation rate differences, desired performance characteristics (e.g., materials that maximize current flow), or combinations thereof, including any of the semiconductor materials disclosed herein.

Isolation feature 122 electrically isolates active device regions and/or passive device regions of device 100. For example, isolation feature 122 separates and electrically isolates an active region of device 100 (having, for example, channel layer 110 disposed between epitaxial source/drains 125) from other device regions and/or devices. Isolation feature 122 includes silicon oxide, silicon nitride, silicon oxynitride, other suitable isolation material (including, for example, silicon, oxygen, nitrogen, carbon, other suitable isolation constituent, etc.), or combinations thereof. Isolation feature 122 may have a multilayer structure. For example, isolation feature 122 can include a bulk dielectric (e.g., an oxide layer) over a dielectric liner (including, for example, silicon nitride, silicon oxide, silicon oxynitride, silicon oxycarbonitride, or combinations thereof). In another example, isolation feature 122 includes a dielectric layer over a doped liner, such as a boron silicate glass (BSG) liner and/or a phosphosilicate glass (PSG) liner. Dimensions and/or characteristics of isolation feature 122 are configured to provide a shallow trench isolation (STI) structure, a deep trench isolation (DTI) structure, a local oxidation of silicon (LOCOS) structure, other suitable isolation structure, or combinations thereof. In the depicted embodiment, isolation feature 122 may be an STI.

Inner spacers 124 are disposed under gate spacers 140 of gate structure 130 and along sidewalls of semiconductor layers 115. Inner spacers 124 are disposed between and separate semiconductor layers 115 and epitaxial source/drains 125. Inner spacers 124 are further disposed between adjacent semiconductor layers 120 and between bottommost semiconductor layer 120 and fin portion 105′. Inner spacers 124 include a dielectric material that includes silicon, oxygen, carbon, nitrogen, other suitable constituent, or combinations thereof, such as silicon oxide, silicon nitride, silicon oxynitride, silicon carbide, silicon oxycarbonitride, etc. In some embodiments, inner spacers 124 include a low-k dielectric material. In some embodiments, dopants (for example, p-type dopants, n-type dopants, or combinations thereof) are introduced into the dielectric material, and inner spacers 124 include doped dielectric material(s).

Epitaxial source/drains 125 include a semiconductor material and may be doped with n-type dopants and/or p-type dopants. When forming a portion of an n-type transistor, epitaxial source/drains 125 can include silicon doped with carbon, phosphorous, arsenic, other n-type dopant, or combinations thereof. When forming a portion of a p-type transistor, epitaxial source/drains 125 can include silicon germanium or germanium doped with boron, other p-type dopant, or combinations thereof. Epitaxial source/drains 125 can include more than one semiconductor layer, where the semiconductor layers include the same or different materials and/or the same or different dopant concentrations. Epitaxial source/drains 125 can include materials and/or dopants that achieve desired tensile stress and/or compressive stress in channel region C. In some embodiments, doped regions, such as heavily doped source/drain (HDD) regions, lightly doped source/drain (LDD) regions, other doped regions, or combinations thereof, are disposed in epitaxial source/drains 125. In some embodiments, doped regions, such as LDD regions, may extend into channel region C. As used herein, source/drain region, epitaxial source/drain, epitaxial source/drain feature, etc. may refer to a source of device 100, a drain of device 100, or a source and/or a drain of multiple devices (including device 100).

Dummy gate 135 extends lengthwise in a direction that is different than (e.g., orthogonal to) the lengthwise direction of channel layer 110. For example, dummy gate 135 extends lengthwise along the y-direction, having a length along the y-direction, a width along the x-direction, and a height along the z-direction. Dummy gate 135 is disposed on a top and sides of channel layer 110, such that dummy gate 135 wraps channel layer 110. Dummy gate 135 has a width W1 along the x-direction. In some embodiments, width W1 is a critical dimension (CD) of gate structure 130, such as a desired gate length (L G) of a gate stack thereof. In some embodiments, width W1 is less than a desired CD of a gate stack. Dummy gate 135 includes a dummy gate electrode 136 and a dummy gate dielectric 138. Dummy gate electrode 136 includes a suitable dummy gate material and dummy gate dielectric 138 includes a suitable dielectric material. For example, dummy gate electrode 136 includes polysilicon (i.e., a poly gate) and dummy gate dielectric 138 includes silicon oxide (i.e., a dummy oxide). Dummy gate 135 can include additional layers, such as a hard mask layer, a capping layer, an interface layer, a diffusion layer, a barrier layer, other suitable layer, or combinations thereof.

Gate spacers 140 are adjacent to and along sidewalls of dummy gate 135. Gate spacers 140 have a spacer height SH above channel layer 110, which is between a top surface of channel layer 110 and a top surface of gate spacers 140. Spacer height SH is substantially the same as gate height GH (i.e., spacer height SH gate height GH). Gate spacers 140 may be and/or include seal spacers, offset spacers, sacrificial spacers, dummy spacers, main spacers, other suitable spacers, or combinations thereof. In FIGS. 3A-3C, gate spacers 140 have single layer structures. For example, each sidewall of dummy gate 135 has a respective, single spacer layer disposed on and/or adjacent thereto. Each gate spacer 140 has a thickness T along the x-direction. In some embodiments, thickness T is about 2 nm to about 8 nm. Gate spacers 140 include a dielectric material, which can include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, etc.). For example, gate spacers 140 can include silicon, oxygen, nitrogen, carbon, and hydrogen and be referred to as SiONCH layers. In some embodiments, a carbon content of gate spacers 140 is less than about 20 atomic percent (at %), such as about 5 to about 20 at %.

Dielectric layer 150 is disposed over substrate 105, isolation feature 122, epitaxial source/drains 125, and gate structure 130. Dielectric layer 150 can have a multilayer structure, such as an interlayer dielectric (ILD) layer over a contact etch stop layer (CESL). The ILD layer includes a dielectric material including, for example, silicon oxide, carbon doped silicon oxide, silicon nitride, silicon oxynitride, tetraethyl orthosilicate (TEOS)-formed oxide, boron silicate glass (BSG), phosphosilicate glass (PSG), borophosphosilicate glass (BPSG), fluorosilicate glass (FSG), Black Diamond® (Applied Materials of Santa Clara, California), xerogel, aerogel, amorphous fluorinated carbon, parylene, benzocyclobutene-based (BCB) dielectric material, SiLK (Dow Chemical, Midland, Michigan), polyimide, other suitable dielectric material, or combinations thereof. In some embodiments, the ILD layer includes a dielectric material having a dielectric constant that is less than a dielectric constant of silicon dioxide (e.g., k<3.9). In some embodiments, the ILD layer includes a dielectric material having a dielectric constant that is less than about 2.5 (i.e., an extreme low-k (ELK) dielectric material), such as porous silicon oxide, silicon carbide (SiC), carbon-doped oxide (e.g., an SiCOH-based material (having, for example, Si—CH₃ bonds)), or combinations thereof, each of which is tuned/configured to have a dielectric constant less than about 2.5. The CESL includes a dielectric material that is different than the dielectric material of the ILD layer. For example, where the ILD layer includes a low-k dielectric material (e.g., porous silicon oxide), the CESL can include silicon and nitrogen, such as silicon nitride, silicon carbonitride, or silicon oxycarbonitride.

In some embodiments, device 100 is received before and/or after forming dielectric layer 150. Forming dielectric layer 150 can include depositing a dielectric material over substrate 105, isolation feature 122, epitaxial source/drains 125, and gate structure 130 and performing a planarization process, such as a chemical mechanical polishing (CMP), on the dielectric material. The planarization process removes any dielectric material from over gate structure 130. Dummy gate 135 (e.g., dummy gate electrode 136) can function as a planarization stop layer, and the planarization process can be performed until reaching and exposing dummy gate 135. The planarization process can planarize a top surface of dielectric layer 150 and a top surface of gate structure 130. In some embodiments, top surface of dielectric layer 150 and top surface of gate structure 130 are substantially planar after the planarization process. In some embodiments, dielectric layer 150 is a portion of a multilayer interconnect (MLI) feature that electrically connects devices (for example, transistors, resistors, capacitors, inductors, etc.), components of devices (for example, gate stacks and/or source/drains), devices within the MLI feature, components of the MLI feature, or combinations thereof, such that the various devices and/or components can operate as specified by design requirements.

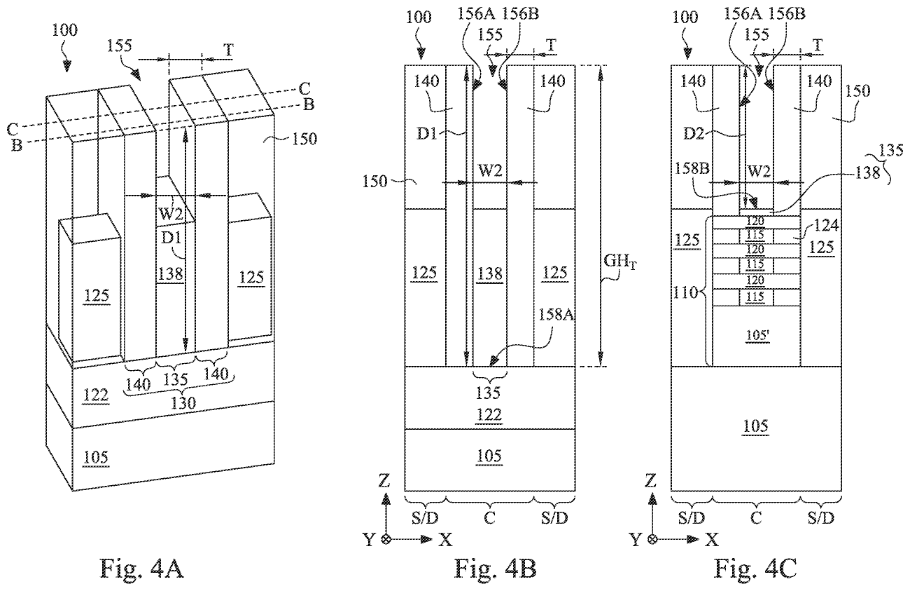

Turning to FIG. 2 and FIGS. 4A-4C, method 50 at block 60 includes partially removing dummy gate 135 to form a gate opening 155 above channel layer 110. For example, gate opening 155 is formed by removing dummy gate electrode 136 without removing (or minimally removing) dummy gate dielectric 138, such that dummy gate dielectric 138 remains over and wrapping channel layer 110. Gate opening 155 has a first portion having a sidewall 156A, a sidewall 156B, and a bottom 158A extending between sidewall 156A and sidewall 156B and a second portion having sidewall 156A, sidewall 156B, and bottom 158B extending between sidewall 156A and sidewall 156B. Sidewall 156A and sidewall 156B are formed by inner sidewalls of opposing gate spacers 140, bottom 158A is formed by isolation feature 122, and bottom 158B is formed by dummy gate dielectric 138. Each of the first portion and the second portion of gate opening 155 has a width W2 along the x-direction between opposing gate spacers 140. In the depicted embodiment, since gate spacers 140 have substantially vertical inner sidewalls extending along the z-direction, width W2 is substantially uniform from top to bottom. In other words, width W2 is substantially the same from a top to a bottom of gate opening 155. Width W2 may be substantially the same as or less than width W1. First portion of gate opening 155 has a depth D1 along the z-direction between top surfaces of gate spacers 140 and a top surface of isolation feature 122. Second portion of gate opening 155 has a depth D2 along the z-direction between top surfaces of gate spacers 140 and a top surface of dummy gate dielectric 138. In the depicted embodiment, depth D1 is substantially the same as total gate height GH T and depth D2 is less than gate height GH (e.g., depth D2=gate height GH−a thickness of dummy gate dielectric 138).

In some embodiments, an etching process can selectively remove dummy gate electrode 136 with respect to dummy gate dielectric 138, gate spacers 140, dielectric layer 150, or combinations thereof. For example, the etching process substantially removes dummy gate electrode 136 but does not remove, or does not substantially remove, dummy gate dielectric 138, gate spacers 140, dielectric layer 150, or combinations thereof. In some embodiments, an etchant is selected for the etching process that etches polysilicon (i.e., dummy gate electrode 136) at a higher rate than dielectric materials (i.e., dummy gate dielectric 138, gate spacers 140, dielectric layer 150, etc.) (i.e., the etchant has a high etch selectivity with respect to polysilicon). The etching process is a dry etch, a wet etch, other suitable etch, or combinations thereof. In some embodiments, the etching process uses a patterned mask layer (i.e., an etch mask) that covers dielectric layer 150 and/or gate spacers 140 but exposes dummy gate 135.

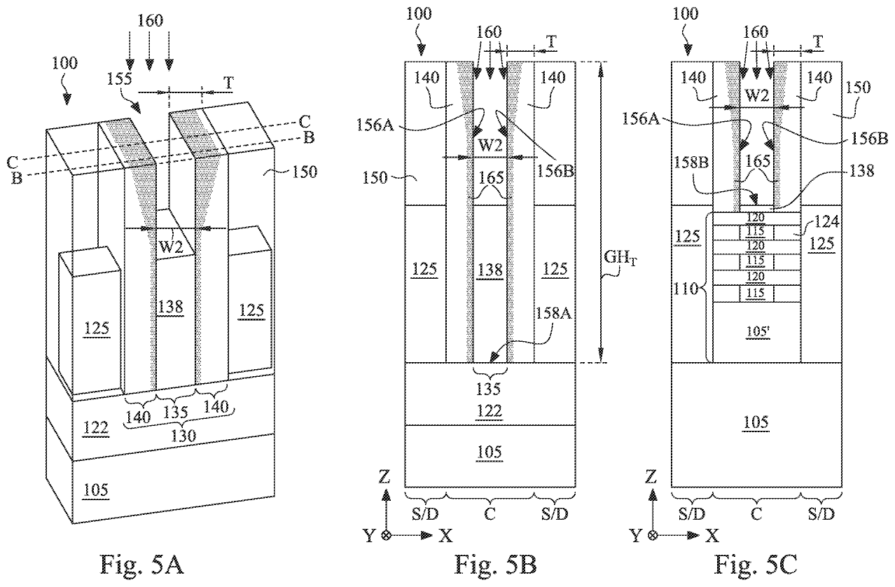

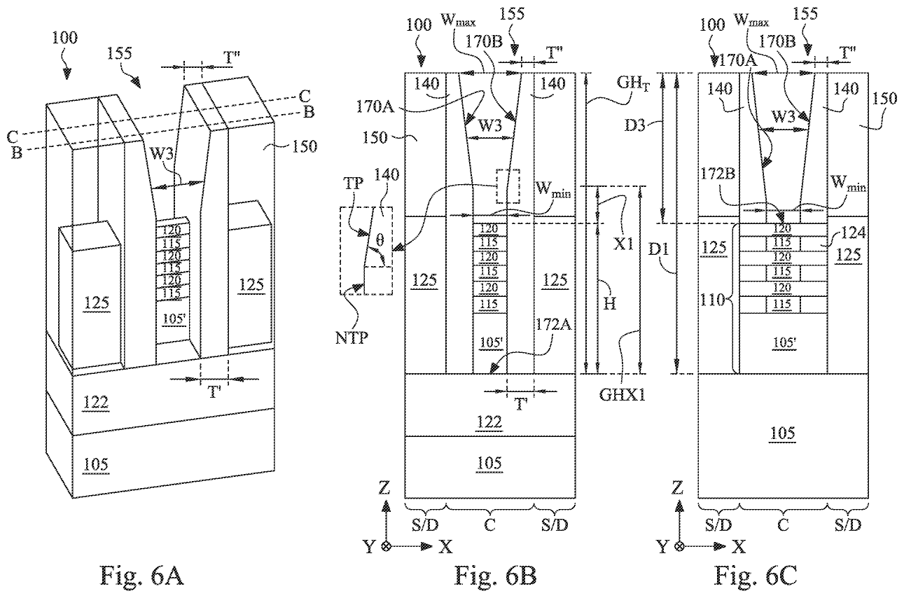

Turning to FIG. 2, FIGS. 5A-5C, and FIGS. 6A-6C, method 50 at block 65 includes modifying a profile of gate opening 155 by performing a treatment process 160 on gate spacers 140 (FIGS. 5A-5C) and removing treated portions 165 of gate spacers 140 (FIGS. 6A-6C). Partially removing dummy gate 135 and modifying the profile of gate opening 155 as described herein provides targeted enlargement of gate opening 155, such as targeted enlargement of a width thereof, at particular gate heights. In some embodiments, an amount of dummy gate 135 removed and treatment process 160 are tuned to enlarge a width of an upper, top portion of gate opening 155, such as a portion of gate opening 155 above channel layer 110. Enlarging a width of the upper, top portion of gate opening 155 can prevent and/or minimize pinch off when filling gate opening 155 with conductive material, thereby improving metal gap fill and inhibiting void/seam formation in the conductive material. In some embodiments, an amount of dummy gate 135 removed and treatment process 160 are tuned to provide gate opening 155 (and thus a gate stack formed therein) with a funnel-shaped profile, which has been observed to enlarge a metal gap filling process window while boosting device performance (for example, by minimizing increases in gate resistance that may arise from void/seam formation). During treatment process 160, a remainder of dummy gate 135 (here, dummy gate dielectric 138) protects features of device 100, such as channel layer 110 and/or gate spacers 140. For example, since the remainder of dummy gate 135 functions as a hard mask (e.g., an oxide protection layer) during treatment process 160 and/or removal of treated portions 165, channel layer 110 and/or portions of gate spacers 140 are not affected and/or damaged (e.g., by plasma damage) by such processing. Accordingly, an extra etch stop layer and/or hard mask is not needed to prevent unintended treatment, over treatment, damage, etc. of gate spacers 140 (which can cause breaks and/or discontinuities therein) and/or unexpected gate width/gate length (L G) variations, thereby simplifying processing. As described herein, the disclosed gate profile modification techniques provide high flexibility to shape and/or taper a gate profile, and a composition of gate spacers 140 (including, for example, silicon, oxygen, nitrogen, carbon, etc.) have been observed to enable spatially, well controlled modification of gate spacers 140. Different embodiments may have different advantages, and no particular advantage is required of any embodiment.

In FIGS. 5A-5C, treatment process 160 changes a composition of portions of gate spacers 140 to enable selective removal of treated portions 165 of gate spacers 140 relative to untreated portions of gate spacers 140. In some embodiments, treatment process 160 is an oxygen plasma treatment that transforms portions of gate spacers 140 into oxide portions (i.e., treatment process 160 partially oxidizes gate spacers 140). For example, the oxygen plasma treatment converts SiONCH into silicon oxide (e.g., SiO₂), such that treated portions 165 are silicon oxide portions of gate spacers 140 and untreated portions are SiONCH portions of gate spacers 140. In some embodiments, the oxygen plasma treatment includes flowing an oxygen-containing precursor gas (e.g., O₂) and a carrier gas (e.g., He) into a process chamber, generating an oxygen-containing plasma therefrom, and bombarding gate spacers 140 with plasma-excited oxygen-containing species (i.e., reactive species) of the oxygen-containing plasma. The reactive species can include radicals, ions, neutrals, electrons, photons, or combinations thereof. The reactive species react with gate spacers 140, for example, by adsorbing on the surfaces thereof and triggering chemical reactions that change a composition of portions of gate spacers 140 and/or producing by-products that desorb from the surfaces of gate spacers 140. In some embodiments, the oxygen-containing plasma includes excited neutral atoms and/or molecules (e.g., oxygen radicals, such as O*, O₂*, etc.), ionized atoms and/or molecules (e.g., oxygen ions, such as O₂⁺, O₂⁻, O⁺, O⁻, etc.), atoms and/or molecules (e.g., O₂, O, etc.), or combinations thereof. The oxygen-containing gas can include O₂ and/or other suitable oxygen-containing precursor (e.g., treatment process 160 is an O₂ plasma treatment). The carrier gas is an inert gas, such as argon, helium, xenon, neon, krypton, other suitable gas, or combinations thereof.

A profile of treated portions 165, and thus a profile of gate opening 155 after removing treated portions 165, is precisely controlled by tuning which reactive species of the oxygen plasma treatment contribute to and/or dominate oxidation of gate spacers 140. When oxygen radicals are the dominant reactive species, the oxygen plasma treatment is non-directional and isotropic, which provides substantially uniform oxidation of gate spacers 140 from top to bottom and thus substantially uniform enlargement of the width of gate opening 155 from top to bottom. When oxygen ions are the dominant reactive species, the oxygen plasma treatment is directional and anisotropic, which provides targeted oxidation of gate spacers 140, and thus targeted enlargement of the width of gate opening 155 and/or targeted gate profile engineering. For example, ion-dominated oxidation can be implemented to enlarge the width at targeted locations of gate opening 155 along gate height GH and/or total gate height GH_{T}. In the depicted embodiment, ion-dominated oxidation increases oxidation of gate spacers 140 at a top of gate opening 155 to provide treated portions 165 with tapered profiles that can sufficiently enlarge gate opening 155 to minimize and/or prevent pinch off (where gate stack layers may fill or close off a top of gate opening 155 before completely filling gate opening 155), thereby improving gap fill during gate stack formation. In FIGS. 5A-5C, each treated portion 165 has a width along the x-direction that decreases from a top of gate opening 155 to about depth D2 thereof and then is substantially the same from about depth D2 to about depth D1.

Treatment process 160 can include a radical-dominated oxidation, an ion-dominated oxidation, or combinations thereof to achieve a desired profile of treated portions 165 and/or a desired gate profile. In the depicted embodiment, treatment process 160 implements both a radical-dominated oxidation and an ion-dominated oxidation, and the radical-dominated oxidation (e.g., uniform enlargement of gate opening 155 from top to bottom) is performed before the ion-dominated oxidation (e.g., tapering and/or funneling enlargement of an upper portion of gate opening 155, such as a portion of gate opening 155 above channel layer 110). In some embodiments, the ion-dominated oxidation is performed before the radical-dominated oxidation. In some embodiments, gate spacers 140 are exposed to more than one radical-dominated oxidation, more than one ion-dominated oxidation, or combinations thereof. As described further below, the present disclosure contemplates removing treated portions of gate spacers 140 after performing all oxidation processes on gate spacers 140 (e.g., treated portions 165 are removed after performing the radical-dominated oxidation and the ion-dominated oxidation), after each oxidation process (e.g., a first removal process removes portions of gate spacers 140 treated by the radical-dominated oxidation and a second removal process removes portions of gate spacers 140 treated by the ion-dominated oxidation), or some other cyclic and/or sequential combination of treatment process(es) and removal process(es).

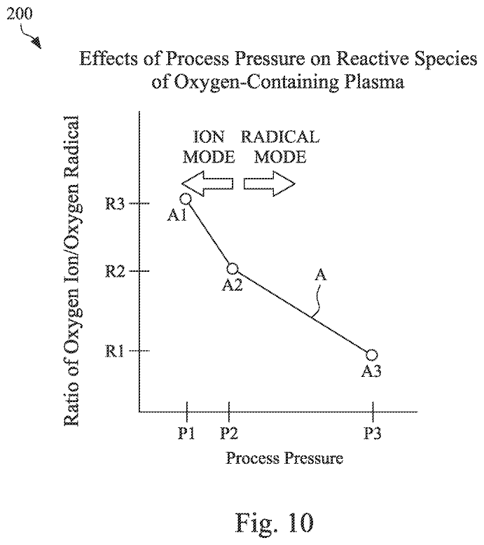

An oxygen ion to oxygen radical ratio (e.g., oxygen ion/oxygen radical) can be tuned to achieve ion-dominated oxidation and/or radical-dominated oxidation during treatment process 160 and obtain desired oxidation profiles of gate spacers 140 and correspondingly desired gate profiles of gate opening 155 (and gate stack subsequently formed therein). In some embodiments, a process pressure of treatment process 160 is tuned to achieve ion-dominated oxidation and/or radical-dominated oxidation. For example, FIG. 10 provides an exemplary plot 200 of a ratio of oxygen ions to oxygen radicals in an oxygen-containing plasma as a function of process pressure obtained by optical emission spectroscopy (OES) analysis according to various aspects of the present disclosure. In plot 200, experimental data includes a data point A1 that corresponds with a pressure P1 and resultant oxygen ion/oxygen radical ratio R3, a data point A2 that corresponds with a pressure P2 and resultant oxygen ion/oxygen radical ratio R2, and a data point A3 that corresponds with a pressure P3 and resultant oxygen ion/oxygen radical ratio R1. Pressure P1 is less than pressure P2, and pressure P2 is less than pressure P3. Ratio R1 is less than ratio R2, and ratio R2 is less than ratio R3. A line A fitted to the experimental data indicates that the oxygen ion/oxygen radical ratio decreases as process pressure increases. In other words, as process pressure increases, an amount of oxygen ions decreases and an amount of oxygen radicals increases. In some instances, process pressures greater than about process pressure P2 can provide oxygen ion/oxygen radical ratios that correspond with radical-dominated oxidation (i.e., radical mode) and process pressures less than about process pressure P2 can provide oxygen ion/oxygen radical ratios that correspond with ion-dominated oxidation (i.e., ion mode). For example, in radical mode, an amount of isotropic oxygen radicals (e.g., O*, O₂*, etc.) in an oxygen-containing plasma may be greater than an amount of anisotropic oxygen ions (e.g., O₂⁺, O₂⁻, O⁺, O⁻, etc.) therein, while in ion mode, an amount of anisotropic oxygen ions in the oxygen-containing plasma may be greater than an amount of isotropic oxygen radicals therein. Accordingly, treatment process 160 can use process pressure to change the oxygen ion/oxygen radical ratio (and/or amounts of oxygen ions and/or oxygen radicals in the oxygen-containing plasma) and thus control which reactive species and/or an amount thereof that dominate and/or contribute to oxidation of gate spacers 140. FIG. 10 has been simplified for the sake of clarity to better understand the inventive concepts of the present disclosure.

In some embodiments, the radical-dominated oxidation can produce a chemical reaction with gate spacers 140 (e.g., SiONCHₓ gate spacers) as follows:

SiONCHₓ+O*→SiO₂+CHₓ, (1)

where, as oxygen radicals (O*), oxygen ions, other reactive species of the oxygen-containing plasma, or combinations thereof impact surfaces of SiONCHₓ gate spacers, portions of SiONCHₓ gate spacers are converted to SiO₂ portions and/or CHₓ by-products desorb from surfaces of gate spacers 140. In some embodiments, treatment process 160 implements higher process pressures, such as those greater than about 1,000 millitorr (mTorr), to decrease the oxygen ion/oxygen radical ratio, which can increase isotropic O* radicals in the oxygen-containing plasma. Increasing pressure and an amount of oxygen radicals in the oxygen-containing plasma provides shorter mean free paths and/or increases dissociative collisions for O₂, which increases isotropy of treatment process 160, providing more isotropic (non-directional) oxidation.

In some embodiments, the ion-dominated oxidation can produce a chemical reaction with gate spacers 140 as follows:

SiONCHₓ+O*→SiO₂+CHₓ(+NHₓ) (2)

where, as reactive species of the oxygen-containing plasma impact gate spacers 140, portions of SiONCHₓ gate spacers are converted to SiO₂ portions and/or CHₓ and/or NHₓ by-products desorb from surfaces of gate spacers 140. In some embodiments, treatment process 160 can implement lower process pressures, such as those less than about 50 mTorr, to increase the oxygen ion/oxygen radical ratio, which can increase anisotropic oxygen ions (e.g., O₂ ions) in the oxygen-containing plasma. Increasing an amount of oxygen ions increases ion energy in the oxygen-containing plasma, and this additional energy can increase surface reactions as the reactive species interact with gate spacers 140 and/or overcome chemical reaction barriers between the oxygen-containing plasma and gate spacers 140. Further, decreasing pressure and an amount of oxygen radicals can provide longer mean free paths, which decreases isotropy of treatment process 160 and can provide anisotropic (directional) oxidation.

Parameters of treatment process 160 are tuned to provide desired oxidation profiles and/or desired resultant gate profiles, such as a flow rate and/or a concentration of an oxygen-containing precursor gas, a flow rate and/or a concentration of a carrier gas, a ratio of the oxygen-containing precursor gas to the carrier gas, a process temperature, a process pressure, a process time, a process power, a process bias (voltage) for exciting the plasma and/or accelerating the plasma, a tilt angle, other suitable parameters, or combinations thereof. In some embodiments, the radical-dominated oxidation is performed with one or more of the following process parameters: a process temperature of about 200 degrees Celsius (° C.) to about 450° C., a process pressure of about 1,000 mTorr to about 3,000 mTorr, a process time of about 30 seconds (s) to about 400 s, a power of about 200 Watts (W) to about 2,500 W, a ratio of an oxygen gas (e.g., O₂) to a noble gas (e.g., He) that is greater than about 80%, or combinations thereof. In some embodiments, the ion-dominated oxidation is performed with one or more of the following process parameters: a process temperature of about 200° C. to about 450° C., a process pressure of about 10 mTorr to about 50 mTorr, a process time of about 30 s to about 400 s, a power of about 200 W to about 2,500 W, a ratio of an oxygen gas (e.g., O₂) to a noble gas (e.g., He) that is about 5% to about 30%, or combinations thereof. In some embodiments, a process pressure and/or an oxygen gas/carrier gas ratio of the radical-dominated oxidation is greater than a process pressure and/or an oxygen gas/carrier gas ratio, respectively, of the ion-dominated oxidation.

The disclosed process parameters are not randomly chosen but are specifically configured to achieve radical-dominated oxidation and ion-dominated oxidation, respectively. For example, if a process pressure is too low (e.g., less than about 1,000 mTorr) during radical-dominated oxidation, then an oxygen ion/oxygen radical ratio may be too high and reduce isotropy of the oxidation, which can hinder uniform enlargement of gate opening 155 as described herein. On the other hand, if the process pressure is too high (e.g., greater than about 3,000 mTorr) during radical-dominated oxidation, then oxidation may be too aggressive and it may be difficult to control an amount and/or a profile of oxidation, which can also hinder uniform enlargement of gate opening 155. In another example, if a process pressure is too high (e.g., greater than about 50 mTorr) during ion-dominated oxidation, then an oxygen ion/oxygen radical ratio and/or ion energy may be too low and impede targeted enlargement of gate opening 155 as described herein. On the other hand, a process tool's capabilities may preclude process pressures less than about 10 mT. As another example, process temperatures less than about 200° C. may slow reaction times and/or provide poor oxidation uniformity, while a process tool's capabilities may preclude process temperatures greater than about 450° C. As yet another example, ample oxidation and gate profile tuning can be achieved during the disclosed process time ranges without decreasing wafer per hour (WPH) too much, thereby ensuring sufficient throughput. Process times less than about 30 s may not enable enough oxidation of gate spacers 140 and thus preclude meaningful gate profile engineering, while process times greater than about 400 s can decrease fabrication productivity, such as WPH, too much. The specifically configured process parameter ranges are thus provided to oxidize gate spacers 140 in a manner that can provide improved gate profile engineering, such as that which can improve reliability of subsequent fabrication processes and/or improve overall performance of device 100 without negatively impacting fabrication throughput and/or fabrication complexity.

As noted above, in FIG. 2 and FIGS. 6A-6C, treated portions 165 of gate spacers 140 are removed, for example, by an oxide removal process at block 65. Further depicted in FIG. 2 and FIGS. 6A-6C, method 50 at block 70 includes removing a remainder of dummy gate 135. In the depicted embodiment, since a remainder of dummy gate 135 is provided by dummy gate dielectric 138 (e.g., a silicon oxide layer), treated portions 165 (e.g., silicon oxide portions of gate spacers 140) and dummy gate dielectric 138 can be removed simultaneously. For example, an etching process can selectively remove treated portions 165 and dummy gate dielectric 138 with respect to gate spacers 140, dielectric layer 150, channel layer 110, or combinations thereof. For example, the etching process substantially removes treated portions 165 and dummy gate dielectric 138 but does not remove, or does not substantially remove, gate spacers 140, dielectric layer 150, channel layer 110, or combinations thereof. In some embodiments, an etchant is selected for the etching process that etches silicon oxide (i.e., treated portions 165 and dummy gate dielectric 138) at a higher rate than other dielectric materials (i.e., gate spacers 140 and/or dielectric layer 150) and semiconductor materials (i.e., channel layer 110) (i.e., the etchant has a high etch selectivity with respect to silicon oxide). The etching process is a dry etch, a wet etch, other suitable etching process, or combinations thereof. In some embodiments, the etching process is a chemical dry etch that implements an etch gas composition that can produce a chemical reaction with treated portions 165 of gate spacers 140 (e.g., silicon oxide portions thereof) and/or dummy gate dielectric 138 as follows:

SiO₂+6HF+2NH₃→(NH₄)₂SiF₆+2H₂O (3)

In some embodiments, the etching process uses a patterned mask layer (i.e., an etch mask) that covers dielectric layer 150 but exposes gate structure 130. In some embodiments, treated portions 165 and dummy gate dielectric 138 are removed separately. For example, a first etch can remove treated portions 165 and a second etch can remove dummy gate dielectric 138.

Gate opening 155 has a different profile after removing treated portions 165 of gate spacers 140 and the remainder of dummy gate 135. For example, gate opening 155 has a first portion having a sidewall 170A, a sidewall 170B, and a bottom 172A extending between sidewall 170A and sidewall 170B and a second portion having sidewall 170A, sidewall 170B, and a bottom 172B extending between sidewall 170A and sidewall 170B. Sidewall 170A and sidewall 170B are formed by inner sidewalls of opposing gate spacers 140, bottom 172A is formed by isolation feature 122, and bottom 172B is formed by channel layer 110. With the modified profile, each of the first portion and the second portion of gate opening 155 has a width W3 along the x-direction between opposing gate spacers 140, and width W3 is greater than width W2. Further, first portion of gate opening 155 has depth D1 along the z-direction between top surfaces of gate spacers 140 and a top surface of isolation feature 122, and second portion of gate opening 155 has a depth D3 along the z-direction between top surfaces of gate spacers 140 and a top surface of channel layer 110. In the depicted embodiment, depth D1 is substantially the same as total gate height GH T and depth D3 is greater than depth D2 and substantially the same as gate height GH.

Gate opening 155 also has a funnel gate profile, where a width of gate opening 155 increases as gate height increases. For example, gate opening 155 has a conically-shaped portion and a tubular-shaped portion (which may be cylindrical-shaped or rectangular-shaped). The conically-shaped portion and the tubular-shaped portion are, respectively, above and below channel layer 110 to provide a width at a top of gate opening 155 that is greater than a width at a bottom of gate opening 155. In some embodiments, along total gate height GH_{T}, since inner sidewall 170A and inner sidewall 170B are substantially vertical (and/or substantially parallel with one another) below channel layer 110 and then tapered above channel layer 110, width W3 is substantially the same from a bottom of gate opening 155 (where gate height=0) to about depth D3 (where gate height≈height H of channel layer 110) and then increases from about depth D3 to a top of gate opening 155 (where gate height=total gate height GH T). In some embodiments, width W3 is a minimum width Wₘᵢₙ from a bottom of gate opening 155 (e.g., depth D1) to about depth D3, and width W3 increases from minimum width Wₘᵢₙ at about depth D3 to a maximum width Wₘₐₓ at a top of gate opening 155. A ratio of maximum width Wₘₐₓ to minimum width Wₘᵢₙ (i.e., Wₘₐₓ/Wₘᵢₙ) is configured to improve subsequent processes, such as filling of gate opening 155 with a gate stack. In some embodiments, Wₘₐₓ/Wₘᵢₙ is about 1 to about 1.5, where Wₘₐₓ/Wₘᵢₙ less than 1 may provide poor gap fill (and thus result in voids and/or seams forming in the gate stack when formed in gate opening 155), while a ratio greater than 1.5 may result in a gate stack that is at risk of being unintentionally electrically connected to a source/drain contact during subsequent processing, which can cause an electrical short.

Further, after gate profile modification (i.e., treatment process 160 and subsequent removal of treated portions 165), gate spacers 140 have a thickness along the x-direction that is less than thickness T. Since inner sidewall 170A and inner sidewall 170B are tapered above channel layer 110 and substantially vertical (and/or substantially parallel with one another) below channel layer 110, a thickness of gate spacers 140 is substantially the same from a bottom of gate opening 155 (where gate height=0) to about depth D3 (where gate height≈height H of channel layer 110) and then decreases from about depth D3 to a top of gate opening 155 (where gate height=total gate height GH_{T}). For example, gate spacers 140 have a thickness T′, which is a maximum thickness of gate spacers 140, from a bottom of gate opening 155 (e.g., depth D1) to about depth D3, and a thickness that decreases from thickness T′ at about depth D3 to a thickness T″, which is a minimum thickness of gate spacers 140, at a top of gate opening 155. In some embodiments, a thickness of gate spacers 140 below channel layer 110 (e.g., thickness T′) is about 3 nm to about 5 nm, and a thickness of gate spacers 140 above channel layer 110 (e.g., thickness T′, thickness T″, and thicknesses therebetween) is about 2 nm to about 4.5 nm.

In some embodiments, the gate profile modification process is tuned to taper inner sidewalls of gate spacers 140 in a manner that enhances filling of gate opening 155. For example, the gate modification process may be tuned to provide a tapering angle θ of tapered portions TP of inner sidewalls of gate spacers 140 (e.g., sidewall 170A and sidewall 170B) with respect to non-tapered portions NTP of the inner sidewalls that is about 30° to about 70°. In the depicted embodiment, tapering angle θ is with respect to the x-axis, which is substantially parallel with a top surface of channel layer 110 and/or a boundary in an X-Y plane between non-tapered portions NTP and tapered portions TP. If the tapering angle is too large (e.g., greater than 70°), a width of gate opening 155 is too narrow to minimize and/or prevent pinch off during gap fill. On the other hand, tuning the gate modification process to obtain a tapering angle that is too small (e.g., less than 30°) may damage device 100. For example, oxidizing gate spacers 140 too aggressively may result in over oxidation of gate spacers 140, exposure of sidewalls of dielectric layer 150 (such as where entire portions of gate spacers 140 are oxidized and removed along sidewalls of dielectric layer 150), discontinuities and/or pits in gate spacers 140, damage to features underlying dummy gate dielectric 138, such as channel layer 110, etc.

In some embodiments, the gate profile modification process is configured to ensure that a width of gate opening 155 begins increasing at a distance X1 above channel layer 110 (i.e., a distance above topmost semiconductor layer 120) and/or a gate height GHX1, where gate height GHX1 is a sum of height H of channel layer 110 and distance X1. Distance X1 represents a maximum distance above channel layer 110 where gate opening 155 can have minimum width Wₘᵢₙ. For example, if gate opening 155 has minimum width Wₘᵢₙ at distances above channel layer 110 that are greater than distance X1, a width of gate opening 155 may not wide enough to minimize and/or eliminate voids and/or seams from forming during filling of gate opening 155 as described herein. In such embodiments, gate spacers 140 may begin tapering at distance X1 and/or gate height GHX1, such that gate spacers 140 have tapering angle θ tapering at distance X1 and/or gate height GHX1. Further, in such embodiments, a total gate spacer thickness above gate height GHX1 is less than a total gate spacer thickness below gate height GHX1. In some embodiments, a total gate spacer thickness above gate height GHX1 is about 2 nm to about 4.5 nm and/or a total gate spacer thickness below gate height GHX1 is about 3 nm to about 5 nm. In embodiments where gate spacers 140 include single layers, a thickness of the single layers below gate height GHX1 may be about 3 nm to about 5 nm, and a thickness of the single layers above gate height GHX1 may be about 2 nm to about 4.5 nm. In some embodiments, such as depicted, distance X1 is about 5 nm, and gate height GHX1 can be referred to as GHS.

Since the gate profile modification process may increase an oxygen content, decrease a nitrogen content, decrease a carbon content, decrease a hydrogen content, or combinations thereof in gate spacers 140, a composition of surfaces of gate spacers 140 that form sidewall 170A and sidewall 170B may be different than a composition of surfaces of gate spacers 140 that form sidewall 156A and sidewall 156B. For example, SiONCH surfaces of gate spacers 140 form sidewall 156A and sidewall 156B before gate profile modification, while SiOₓN_{y}C_{1-x-y} surfaces of gate spacers 140 form sidewall 170A and sidewall 170B after gate profile modification, where x is a number of oxygen atoms, y is a number of nitrogen atoms, x and y are greater than 1, and x is much greater than y (x>>y). In some embodiments, after gate profile modification, an oxygen content of gate spacers 140 is about 50 at % to about 70 at %.

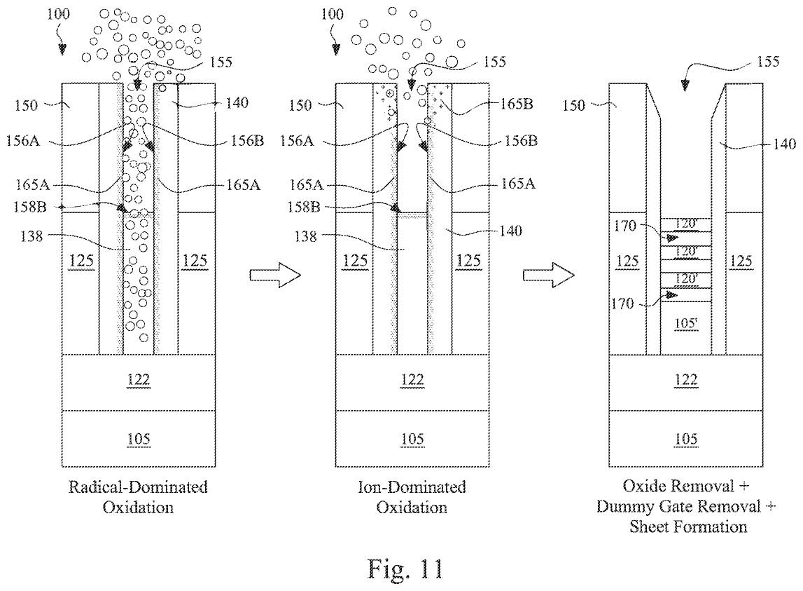

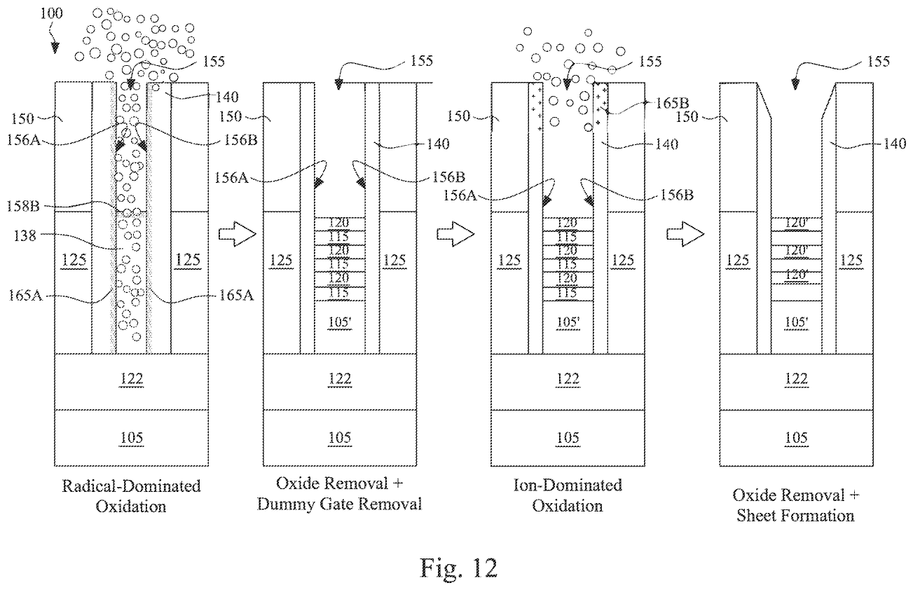

As noted above, the gate profile modification techniques described herein can implement any suitable sequence of gate spacer treatment/removal. FIG. 11 and FIG. 12 illustrate fragmentary cross-sectional views of device 100, in portion or entirety, at various fabrication stages using different gate profile modification sequences according to various aspects of the present disclosure. The gate profile modification sequences in FIG. 11 and FIG. 12 are performed after removing dummy gate electrode 136 and exposing dummy gate dielectric 138 (i.e., a dummy oxide protects channel layer 110 during the gate profile modification sequences). In FIG. 11, treated portions of gate spacers 140 are removed after performing both a radical-dominated oxidation (providing treated portions 165A of gate spacers 140) and an ion-dominated oxidation (providing treated portions 165B of gate spacers 140). Treated portions 165 (here, treated portions 165A and treated portions 165B) are removed in a single step (e.g., a one-step oxide removal). In contrast, in FIG. 12, treated portions of gate spacers 140 are removed after each oxidation. For example, treated portions 165A are removed after radical-dominated oxidation and before ion-dominated oxidation and treated portions 165B are removed after ion-dominated oxidation. Treated portions 165 (here, treated portions 165A and treated portions 165B) are thus removed in two steps (e.g., a two-step oxide removal). The gate profile modification sequence implemented may be selected depending on whether time and/or precision is a primary concern. For example, the one-step oxide removal in FIG. 11 can reduce overall process/fabrication time of device 100, while the two-step oxide removal in FIG. 12 can provide more control of the gate spacer profile (and thus provide finer tuning and/or control of a gate profile and/or critical dimensions of a gate stack). FIG. 11 and FIG. 12 have been simplified for the sake of clarity to better understand the inventive concepts of the present disclosure. Additional features can be added in device 100, and some of the features described can be replaced, modified, or eliminated in other embodiments of device 100.

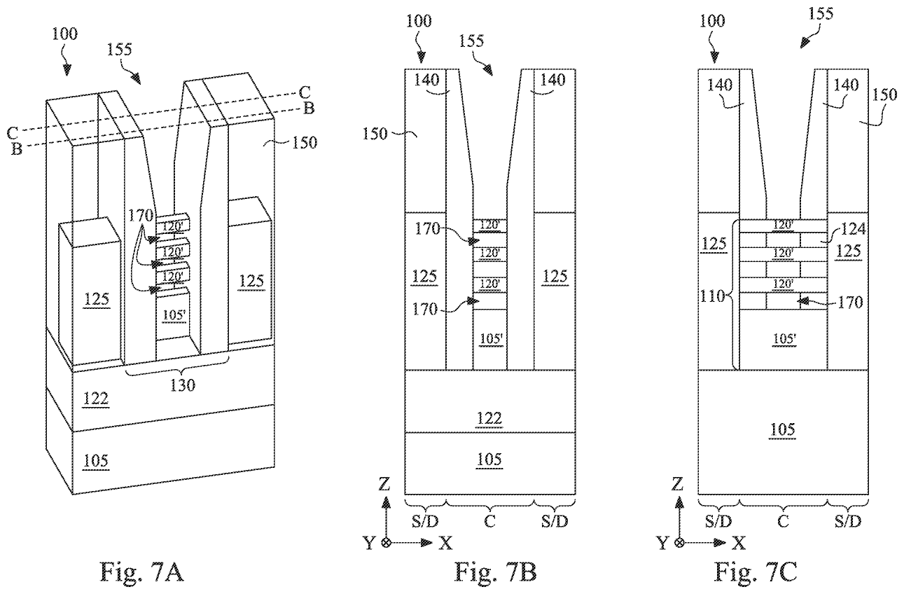

Turning to FIG. 2 and FIGS. 7A-7C, method 50 at block 75 includes performing a channel release process. For example, semiconductor layers 115 exposed by gate opening 155 are selectively removed to form air gaps 170 between semiconductor layers 120 and between semiconductor layers 120 and fin portion 105′, thereby suspending semiconductor layers 120 in channel region C. In the depicted embodiment, three suspended semiconductor layers 120, which are referred to hereafter as channel layers 120′, vertically stacked along the z-direction provide three channels through which current can flow between respective epitaxial source/drains 125 during operation of device 100. In some embodiments, an etching process is performed to selectively etch semiconductor layers 115 with minimal (to no) etching of semiconductor layers 120, fin portion 105′, gate spacers 140, inner spacers 124, dielectric layer 150, or combinations thereof. In some embodiments, an etchant is selected for the etch process that etches silicon germanium (i.e., semiconductor layers 115) at a higher rate than silicon (i.e., semiconductor layers 120 and fin portion 105′) and dielectric materials (i.e., gate spacers 140, inner spacers 124, dielectric layer 150, etc.) (i.e., the etchant has a high etch selectivity with respect to silicon germanium). The etching process is a dry etch, a wet etch, other suitable etching process, or combinations thereof. In some embodiments, before performing the etching process, an oxidation process can be implemented to convert semiconductor layers 115 into semiconductor oxide features (e.g., silicon germanium oxide), and the etching process then removes the semiconductor oxide features. In some embodiments, during and/or after removing semiconductor layers 115, an etching process is performed to modify a profile of semiconductor layers 120 to achieve target dimensions and/or target shapes for channel layers 120′.

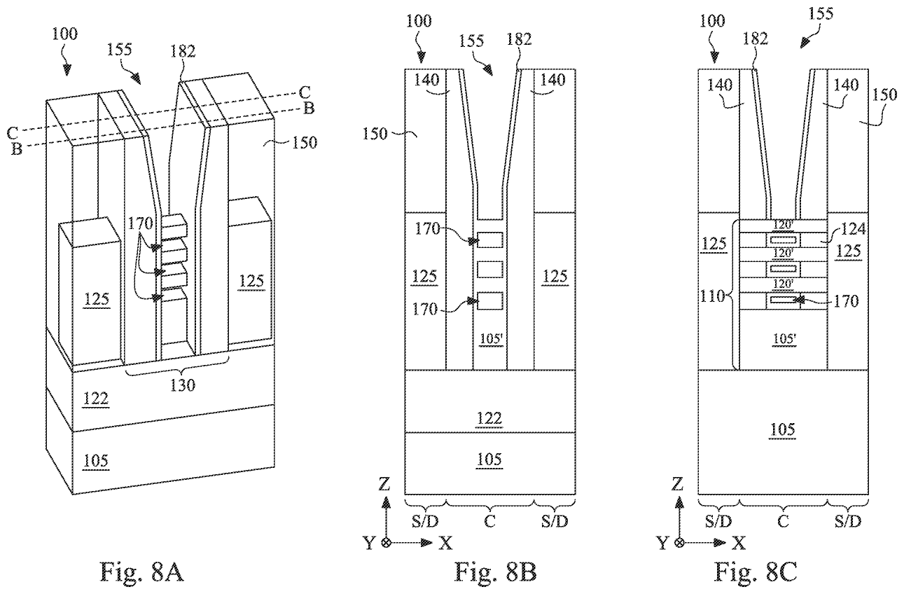

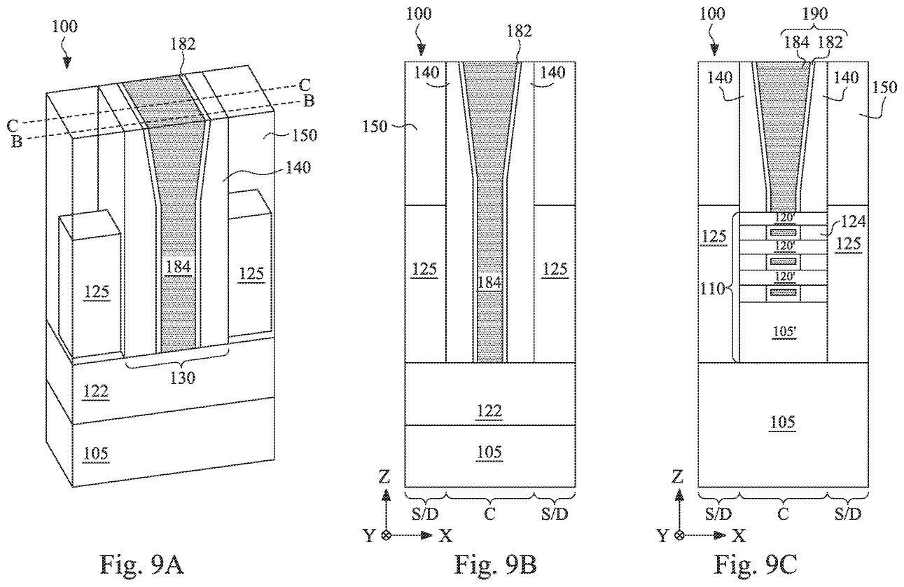

Turning to FIG. 2, FIGS. 8A-8C, and FIGS. 9A-9C, method 50 at block 80 includes forming a gate stack 190 in gate opening 155. Gate stack 190 fills gate opening 155 and, in the depicted embodiment, air gaps 170. Gate stack 190 and gate spacers 140 may be collectively referred to as gate structure 130. Gate stack 190 is disposed between channel layers 120′ and between channel layers 120′ and fin portion 105′. In the X-Z plane (FIG. 9B and FIG. 9C), gate stack 190 is disposed between gate spacers 140 and inner spacers 124. In the Y-Z plane, gate stack 190 at least partially surrounds (e.g., encircles) channel layers 120′. A width of gate stack 190 is tapered in an upper portion thereof, such as a portion above channel layer 110. For example, the width of gate stack increases from about gate height GHX1 to total gate height GHX T, and the width of gate stack 190 is substantially uniform below about gate height GHX1. In the depicted embodiment, gate stack 190 includes a gate dielectric 182 (e.g., a gate dielectric layer) and a gate electrode 184 (e.g., a work function layer and a bulk metal layer). Gate stack 190 may include numerous other layers, such as a capping layer, an interface layer, a diffusion layer, a barrier layer, a hard mask layer, or combinations thereof.

In FIGS. 8A-8C, gate dielectric 182 is formed over channel layers 120′. Gate dielectric 182 has a substantially uniform thickness and partially fills gate opening 155. Gate dielectric 182 includes a high-k dielectric material, such as HfO₂, HfSiO, HfSiO₄, HfSiON, HfLaO, HfTaO, HfSiO, HfZrO, HfAlOₓ, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃(BTO), (Ba,Sr)TiO₃ (BST), Si₃N₄, HfO₂—Al₂O₃, other suitable high-k dielectric material, or combinations thereof. High-k dielectric material generally refers to dielectric materials having a high dielectric constant, for example, greater than that of silicon dioxide (k≈3.9). In some embodiments, gate dielectric 182 includes another suitable dielectric material, such as SiO₂ or other suitable dielectric material. In some embodiments, gate dielectric 182 has a multilayer structure, such as a high-k dielectric layer disposed over an interfacial layer (e.g., a dielectric layer that includes SiO₂, SiGeOₓ, HfSiO, SiON, other suitable material, or combinations thereof).

In FIGS. 9A-9C, gate electrode 184 is formed over gate dielectric 182 and fills a remainder of gate opening 155. Gate electrode 184 includes a conductive material, such as A1, Cu, Ti, Ta, W, Mo, Co, TaN, NiSi, CoSi, TiN, WN, TiAl, TiAlN, TaCN, TaC, TaSiN, other conductive material, or combinations thereof. In some embodiments, gate electrode 184 includes a work function layer and a bulk (fill) conductive layer. The work function layer is a conductive layer tuned to have a desired work function (such as an n-type work function or a p-type work function), and the conductive bulk layer is a conductive layer formed over the work function layer. In some embodiments, the work function layer includes n-type work function material, such as Ti, Ag, Mn, Zr, TaAl, TaAlC, TiAlN, TaC, TaCN, TaSiN, other suitable n-type work function material, or combinations thereof. In some embodiments, the work function layer includes a p-type work function material, such as Ru, Mo, Al, TiN, TaN, WN, ZrSi₂, MoSi₂, TaSi₂, NiSi₂, WN, other suitable p-type work function materials, or combinations thereof. The bulk conductive layer includes a suitable conductive material, such as Al, W, Cu, Ti, Ta, polysilicon, metal alloys, other suitable materials, or combinations thereof.

In some embodiments, forming gate stacks 190 includes depositing a gate dielectric layer over device 100 that partially fills gate opening 155 (and, in some embodiments, gaps 170), depositing a gate electrode layer over the gate dielectric layer that fills a remainder of gate opening 155, and performing a planarization process, such as CMP, on the gate electrode layer and/or the gate dielectric layer, thereby forming gate stack 190 having gate dielectric 182 and gate electrode 184. The CMP process can stop upon reaching dielectric layer 150. The gate dielectric layer and/or the gate electrode layer can include more than one layer. The deposition processes can include atomic layer deposition (ALD), physical vapor deposition (PVD), chemical vapor deposition (CVD), high density plasma CVD (HDPCVD), metal organic CVD (MOCVD), remote plasma CVD (RPCVD), plasma enhanced CVD (PECVD), low-pressure CVD (LPCVD), atomic layer CVD (ALCVD), atmospheric pressure CVD (APCVD), sub-atmospheric CVD (SACVD), metal organic CVD (MOCVD), thermal oxidation, chemical oxidation, plating, other suitable methods, or combinations thereof. Because gate opening 155 is enlarged as described herein, the gate dielectric layer and/or the gate electrode layer can uniformly fill gate opening 155 from top to bottom (e.g., without pinch off and/or void/seam formation). In some embodiments, width W1 (and thus width W2) is intentionally designed less than a desired CD for gate stack 190 and enlarging width W2 to width W3 as described herein improves metal gap fill while providing gate stack 190 with the desired CD.

As described herein, device 100 is fabricated as a GAA transistor having an improved gate profile (i.e., a transistor having a gate that surrounds at least one suspended channel (for example, nanowires, nanosheets, nanobars, etc.), where the at least one suspended channel extends between epitaxial source/drains). The GAA transistor may be a p-type GAA transistor or an n-type GAA transistor. In the depicted embodiment, the GAA transistor includes a channel (e.g., channel layers 120), source/drains (e.g., epitaxial source/drains 125), and a gate (e.g., gate stack 190). The gate engages the channel between the source/drains, and current can flow between the source/drains (e.g., between source and drain or vice versa) during operation. The gate is on a top and a bottom of the channel in the X-Z plane, and the gate surrounds the channel in the Y-Z plane (e.g., gate stack 190 is disposed on a top, a bottom, and sidewalls of channel layers 120). In some embodiments, device 100 is fabricated as a FinFET. In such embodiments, gate stack 190 partially surrounds and/or wrap the channel. For example, the channel is a portion of a semiconductor fin extending from substrate 105, gate stack 190 is on a top of the semiconductor fin in the X-Z plane, and gate stack 190 wraps the semiconductor fin in the Y-Z plane (i.e., gate stack 190 is disposed on a top and sidewalls of the semiconductor fin).

In some embodiments, fabrication of device 100 includes fabricating a remainder of the MLI feature over dielectric layer. The MLI feature includes a combination of dielectric layers and electrically conductive layers (e.g., patterned metal layers formed by conductive lines, conductive vias, conductive contacts, or combinations thereof) configured to form interconnect (routing) structures, which may provide interconnections (e.g., wiring) between the various devices and/or components of device 100. The conductive layers form vertical interconnect structures, such as device-level contacts and/or vias, that connect horizontal interconnect structures, such as conductive lines, in different layers/levels (or different planes) of the MLI feature. In some embodiments, the interconnect structures route electrical signals between devices and/or components of device 100 and/or the MLI feature. In some embodiments, the interconnect structures distribute electrical signals (for example, clock signals, voltage signals, and/or ground signals) to the devices and/or the device components of device 100 and/or the MLI feature. In some embodiments, the conductive lines can include Cu, Al, AlCu, Ru, Co, other suitable electrically conductive material, or combinations thereof. In some embodiments, the contacts and/or the vias can include Cu, Al, AlCu, Ru, Co, W, other suitable electrically conductive material, or combinations thereof. In some embodiments, the dielectric layers can include silicon oxide or a silicon-and-oxygen containing material where silicon exists in various suitable forms. In some embodiments, the dielectric layers include low-k dielectric layers (e.g., having a dielectric constant less than that of SiO₂, which is about 3.9), such as TEOS oxide, USG, doped silicon oxide (e.g., BPSG, FSG, PSG, BSG, other doped silicon oxide, or combinations thereof), other suitable low-k dielectric materials, or combinations thereof.

In some embodiments, fabrication of device 100 includes forming various contacts that can facilitate operation of device 100. For example, one or more dielectric layers, similar to dielectric layer 150, can be formed over gate structure 130 (including gate stack 190) and dielectric layer 150. Contacts can then be formed in dielectric layer 150 and/or dielectric layers disposed over dielectric layer 150. For example, contacts are respectively formed that are physically and/or electrically coupled to gate stack 190 and at least one of epitaxial source/drains 125, respectively, of device 100. Contacts include a conductive material, such as metal. Metals include aluminum, aluminum alloy (such as aluminum/silicon/copper alloy), copper, copper alloy, titanium, titanium nitride, tantalum, tantalum nitride, tungsten, polysilicon, metal silicide, other suitable metals, or combinations thereof. The metal silicide may include nickel silicide, cobalt silicide, tungsten silicide, tantalum silicide, titanium silicide, platinum silicide, erbium silicide, palladium silicide, or combinations thereof. In some embodiments, dielectric layers disposed over dielectric layer 150 and the contacts (for example, a gate contact and/or source/drain contacts extending through dielectric layer 150 and/or dielectric layers disposed thereover) are a portion of the MLI feature disposed over substrate 105.

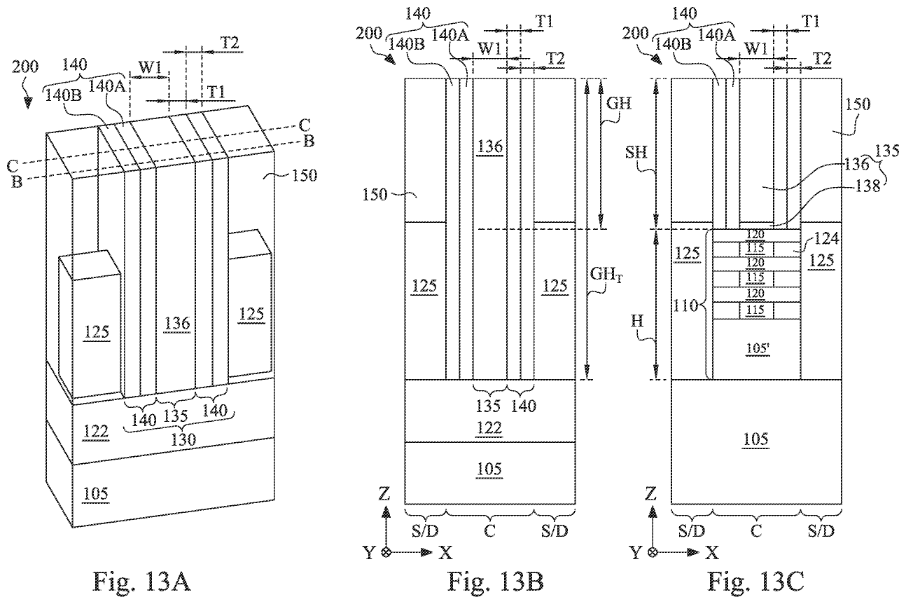

FIGS. 13A-19A, FIGS. 13B-19B, and FIGS. 13C-19C are various views of a device 200, in portion or entirety, at various fabrication stages (such as those associated with method 50 of FIG. 2) according to various aspects of the present disclosure. FIGS. 13A-19A are fragmentary perspective views of device 200. FIGS. 13B-19B are fragmentary cross-sectional views of device 200 taken along lines B-B of FIGS. 13A-19A, respectively. FIGS. 13C-19C are fragmentary cross-sectional views of device 200 taken along lines C-C of FIGS. 13A-19A, respectively. FIGS. 13A-19A, FIGS. 13B-19B, and FIGS. 13C-19C have been simplified for the sake of clarity to better understand the inventive concepts of the present disclosure. Additional features can be added in device 200, and some of the features described below can be replaced, modified, or eliminated in other embodiments of device 200.

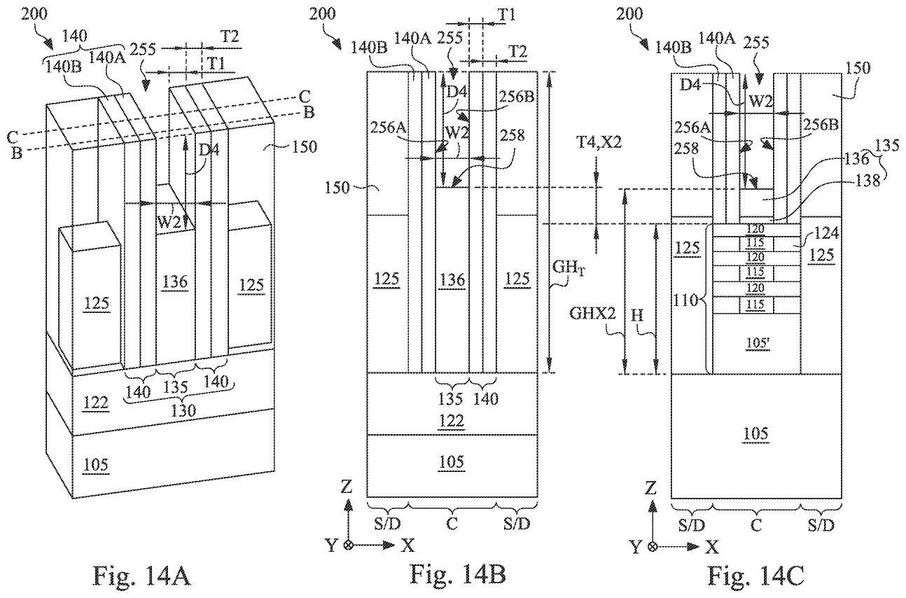

Fabrication of device 200 is similar in many respects to fabrication of device 100. For example, fabrication includes forming a gate structure having a dummy gate and gate spacers over a channel layer (FIGS. 13A-13C, fabrication of which and features of which are similar to that described with reference to FIGS. 3A-3C) and partially removing the dummy gate to form a gate opening (FIGS. 14A-14C, fabrication of which and features of which are similar to that described with reference to FIGS. 4A-4C). In FIGS. 13A-13C, device 200 includes substrate 105, channel layer 110 (having fin portion 105′, semiconductor layers 115, and semiconductor layers 120), isolation feature 122, inner spacers 124, epitaxial source/drains 125, gate structure 130 having dummy gate 135 and gate spacers 140, and dielectric layer 150. Dummy gate 135 includes dummy gate electrode 136 and dummy gate electrode 138.

In FIGS. 13A-13C, gate spacers 140 have a multilayer structure, instead of a single layer structure. For example, a pair of spacers is disposed on each side of dummy gate 135, and each gate spacer 140 includes a gate spacer 140A adjacent to a respective sidewall of dummy gate 135 and a gate spacer 140B adjacent to gate spacer 140A. Gate spacers 140A and gate spacers 140B may be referred to as inner gate spacers and outer gate spacers, respectively. Gate spacers 140A and gate spacers 140B have different compositions to provide different oxidation rates and/or etching selectivity to facilitate gate profile modification during a gate replacement process. For example, inner gate spacers 140A are SiONCH layers having a first carbon content, and outer gate spacers 140B are SiONCH layers having a second carbon content. The second carbon content is less than the first carbon content. In some embodiments, the first carbon content is about 5 at % to about 20 at %. In some embodiments, the second carbon content is less than about 5 at %. Gate spacers 140A and gate spacers 140B also have a thickness T1 and a thickness T2, respectively, along the x-direction. In some embodiments, thickness T1 is about 1 nm to about 4 nm. In some embodiments, thickness T2 is about 1 nm to about 4 nm.

In FIGS. 14A-14C, instead of completely removing dummy gate electrode 136, fabrication of device 200 includes partially removing dummy gate electrode 136 to form a gate opening 255, such that dummy gate electrode 136 and dummy gate dielectric 138 remain over and wrapping channel layer 110. Dummy gate electrode 136 can protect device features, such as channel layer 110, during gate profile modification. For example, dummy gate electrode 136 (in addition to dummy gate dielectric 138) can act as a hard mask when treating gate spacers 140, such as by oxygen plasma treatment, and/or removing treated portions of gate spacers 140. In some embodiments, an etching process can selectively remove dummy gate electrode 136 with respect to gate spacers 140, dielectric layer 150, or combinations thereof. For example, the etching process substantially removes dummy gate electrode 136 but does not remove, or does not substantially remove, gate spacers 140, dielectric layer 150, or combinations thereof. In some embodiments, an etchant is selected for the etching process that etches polysilicon (i.e., dummy gate electrode 136) at a higher rate than dielectric materials (i.e., gate spacers 140, dielectric layer 150, etc.) (i.e., the etchant has a high etch selectivity with respect to polysilicon). The etching process is a dry etch, a wet etch, other suitable etch, or combinations thereof. In some embodiments, the etching process uses a patterned mask layer (i.e., an etch mask) that covers dielectric layer 150 and/or gate spacers 140 and exposes dummy gate 135.

Gate opening 255 has a sidewall 256A, a sidewall 256B, and a bottom 258 extending between sidewall 256A and sidewall 256B. Sidewall 256A and sidewall 256B are formed by inner sidewalls of opposing inner gate spacers 140A and bottom 258 is formed by dummy gate electrode 136. Gate opening 255 has width W2, and since gate spacers 140 have substantially vertical inner sidewalls extending along the z-direction, width W2 is substantially uniform from top to bottom. In other words, width W2 is substantially the same from a top to a bottom of gate opening 255. Width W2 may be substantially the same as or less than width W1. Gate opening 255 also has a depth D4 along the z-direction between a top of gate spacers 140 and a top of dummy gate electrode 136. Depth D4 is less than gate height GH, and a portion of dummy gate electrode 136 that remains over a top surface of channel layer 110 has a thickness T4 along the z-direction (e.g., depth D4=gate height GH−thickness T4). Thickness T4 corresponds with a distance X2 above channel layer 110 along the z-direction. In some embodiments, depth D4 is about ¼ of total gate height GH_{T} to about ½ of total gate height GH_{T}, which correspond with a removed amount (e.g., thickness) of dummy gate electrode 136 that is ¼ total gate height GH_{T} to about ½ total gate height GH_{T}. Depending on technology node, removing amounts of dummy gate electrode 136 that are less than about ¼ total gate height GH_{T} may hinder meaningful gate profile modification, while removing amounts of dummy gate electrode 136 that are greater than about ½ total gate height GH_{T} may expose too much of gate spacers 140, which can lead to more aggressive gate profile modification that can cause breaks and/or discontinuities in gate spacers 140 and/or risk damage to epitaxial source/drains 125 (e.g., pitting) during the gate profile modification. In some embodiments, depth D4 is about 5 nm to about 30 nm.

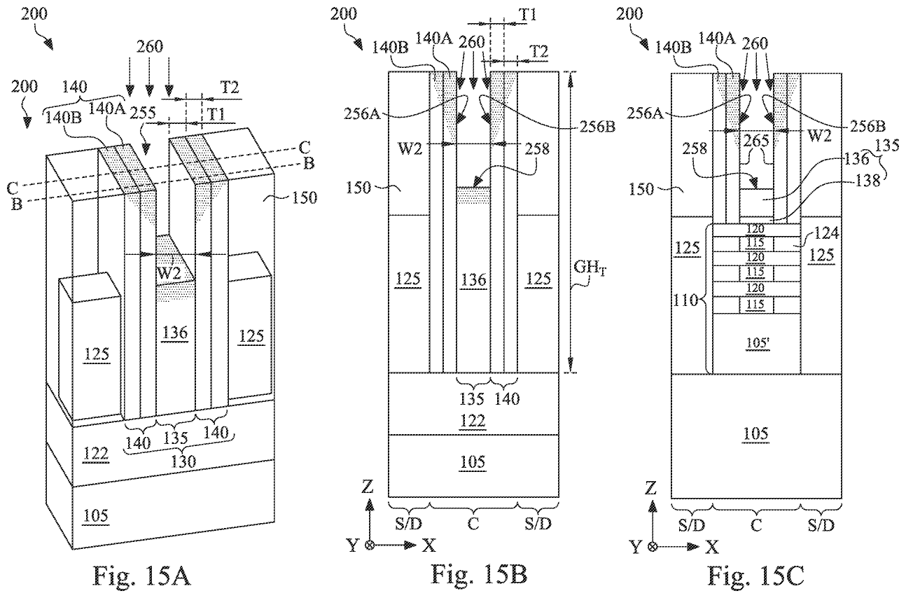

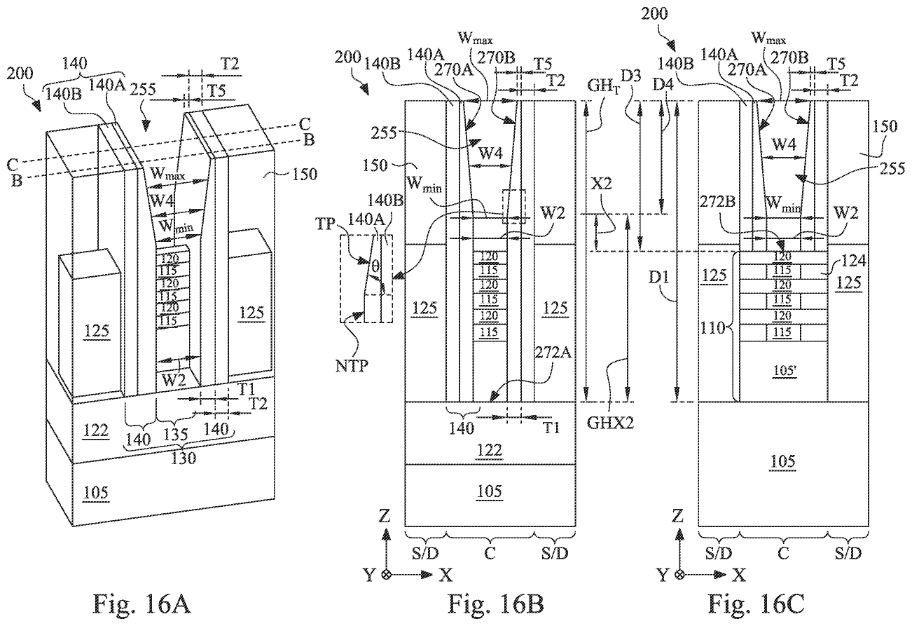

After partial removal, dummy gate 135 has a gate height GHX2 that is greater than height H (e.g., gate height GHX2=height H+thickness T4=total gate height GH_{T}−depth D4). Fabrication can proceed with modifying a profile of the gate opening by performing a treatment process 260 on gate spacers 140 (FIGS. 15A-15C, fabrication of which and features of which are similar to that described with reference to FIGS. 5A-5C), removing treated portions 265 of gate spacers 140 (FIGS. 16A-16C, fabrication of which and features of which are similar to that described with reference to FIGS. 6A-6C), and removing a remainder of dummy gate 135 (FIGS. 16A-16C). Since dummy gate 135 has gate height GHX2, gate profile modification is targeted to a portion of gate structure 130 above gate height GHX2, and a modified profile of gate opening 255 is different than a modified profile of gate opening 155. For example, gate opening 255 has a first portion having a sidewall 270A, a sidewall 270B, and a bottom 272A extending between sidewall 270A and sidewall 270B and a second portion having sidewall 270A, sidewall 270B, and a bottom 272B extending between sidewall 270A and sidewall 270B. Sidewall 270A and sidewall 270B are formed by inner sidewalls of opposing inner gate spacers 140A, bottom 272A is formed by isolation feature 122, and bottom 272B is formed by channel layer 110. Each of the first portion and the second portion of gate opening 255 has a width W4 along the x-direction between inner gate spacers 140A above gate height GHX2 and width W2 below gate height GHX2. In some embodiments, width W4 is about equal to a desired CD for a gate stack of device 200, and width W2 is less than the desired CD. In some embodiments, width W2 is about equal to a desired CD, and width W4 increases from the desired CD to a width greater than the desired CD. Further, first portion of gate opening 255 has depth D1, and second portion of gate opening 255 has depth D3. In the depicted embodiment, depth D1 is substantially the same as total gate height GH T and depth D3 is greater than depth D4.

Gate opening 255 also has a different funnel gate profile. For example, along total gate height GH_{T}, since inner sidewall 270A and inner sidewall 270B are substantially vertical (and/or substantially parallel with one another) below gate height GHX2 and then tapered above gate height GHX2, gate opening 255 has width W2 from a bottom of gate opening 255 (where gate height=0) to about depth D4 (where gate height gate height GHX2) and width W4 at about depth D4 to a top of gate opening 255 (where gate height=total gate height GH T). In some embodiments, width W4 increases along a gate height. For example, width W4 increases from a minimum width Wₘᵢₙ at about depth D4 to a maximum width Wₘₐₓ at a top of gate opening 255. In some embodiments, Wₘₐₓ/Wₘᵢₙ is about 1 to about 1.5. In some embodiments, width W2 is greater than or equal to minimum width Wₘᵢₙ. It is noted that, in contrast to gate profile modification associated with device 100, a width of gate opening 255 is not modified where dummy gate electrode 136 remains (e.g., below a top of channel layer 110, width W2 of gate opening 155 is increased to width W3 in device 100, whereas gate opening 255 maintains width W2 below the top of channel layer in device 200).

Further, after gate profile modification of device 200, gate spacers 140A have a thickness T5 along the x-direction above gate height GHX2 and thickness T1 below gate height GHX2. Thickness T5 is less than thickness T1. In some embodiments, a thickness of gate spacers 140A is substantially the same from a bottom of gate opening 255 (where gate height=0) to about depth D4 (where gate height gate height GHX2) (e.g., thickness T1) and then decreases from about depth D4 to a top of gate opening 255 (where gate height=total gate height GH T) (e.g., thickness T5). In some embodiments, thickness T5 decreases from a maximum thickness of gate spacers 140 (e.g., thickness T1) at about depth D4 to a minimum thickness of gate spacers 140A at a top of gate opening 255. Further, a total gate spacer thickness above channel layer 110 (i.e., a sum of thickness T2 and thickness T5) is less than a total gate spacer thickness below channel layer 110 (i.e., a sum of thickness T2 and thickness T1). In some embodiments, a total gate spacer thickness above channel layer 110 is about 2 nm to about 4.5 nm. In some embodiments, a total gate spacer thickness below channel layer 110 is about 3 nm to about 5 nm.

In some embodiments, the gate profile modification process is tuned to taper inner sidewalls of gate spacers 140 in a manner that enhances filling of gate opening 255. For example, the gate modification process may be tuned to provide a tapering angle θ of tapered portions TP of inner sidewalls of gate spacers 140 (e.g., sidewall 270A and sidewall 270B) with respect to non-tapered portions NTP of the inner sidewalls that is about 30° to about 70°. In some embodiments, a composition of surfaces of gate spacers 140 that form sidewall 270A and sidewall 270B may be different than a composition of surfaces of gate spacers 140 that form sidewall 256A and sidewall 256B. For example, SiONCH surfaces of gate spacers 140 form sidewall 256A and sidewall 256B before gate profile modification, while SiOₓN_{y}C_{1-x-y} surfaces of gate spacers 140 form sidewall 270A and sidewall 270B after gate profile modification. In some embodiments, after gate profile modification, an oxygen content of gate spacers 140 (in the depicted embodiment, inner gate spacers 140A) is about 50 at % to about 70 at %.

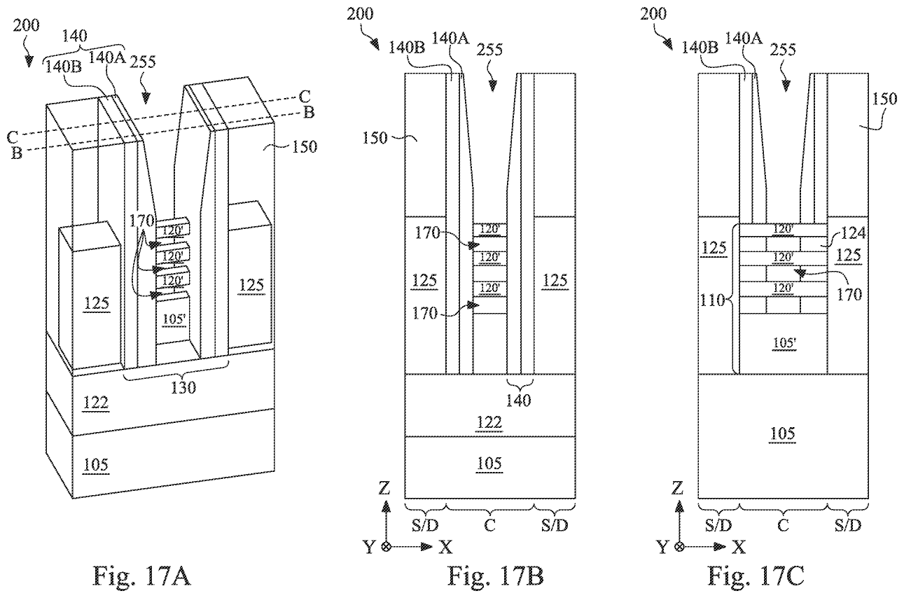

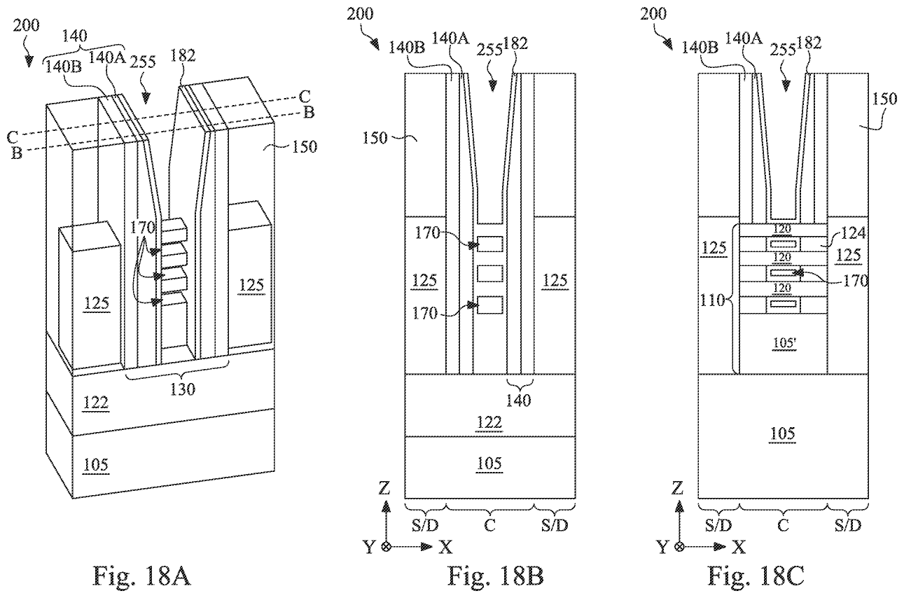

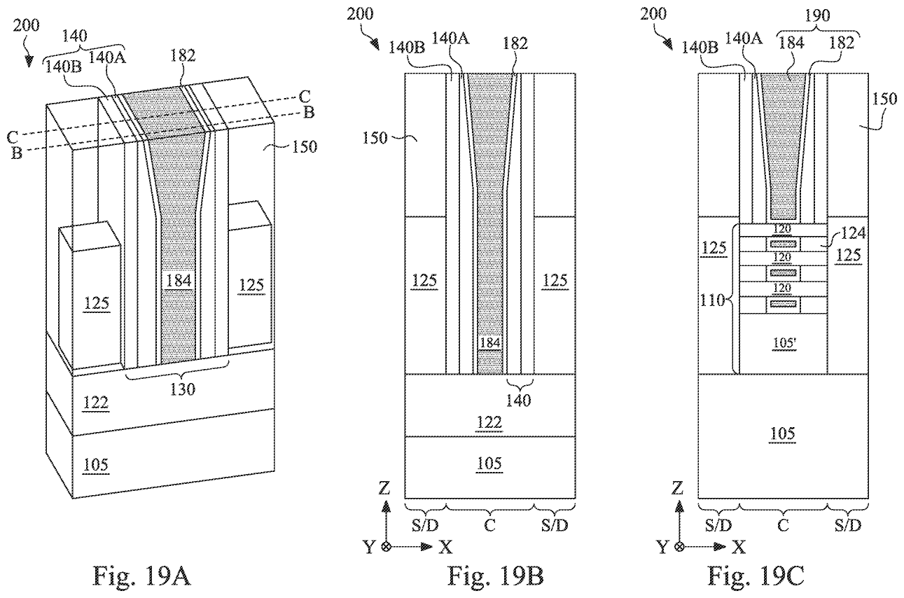

Fabrication further includes performing a channel release process (FIGS. 17A-17C, fabrication of which and features of which are similar to that described with reference to FIGS. 7A-7C) and forming a gate stack 190 in gate opening 255 (FIGS. 18A-18C and FIGS. 19A-19C, fabrication of which and features of which are similar to that described with reference to (FIGS. 8A-8C and FIGS. 9A-9C, respectively). Because gate opening 255 is enlarged as described herein, the gate dielectric layer and/or the gate electrode layer can uniformly fill gate opening 255 from top to bottom (e.g., without pinch off and/or void/seam formation).

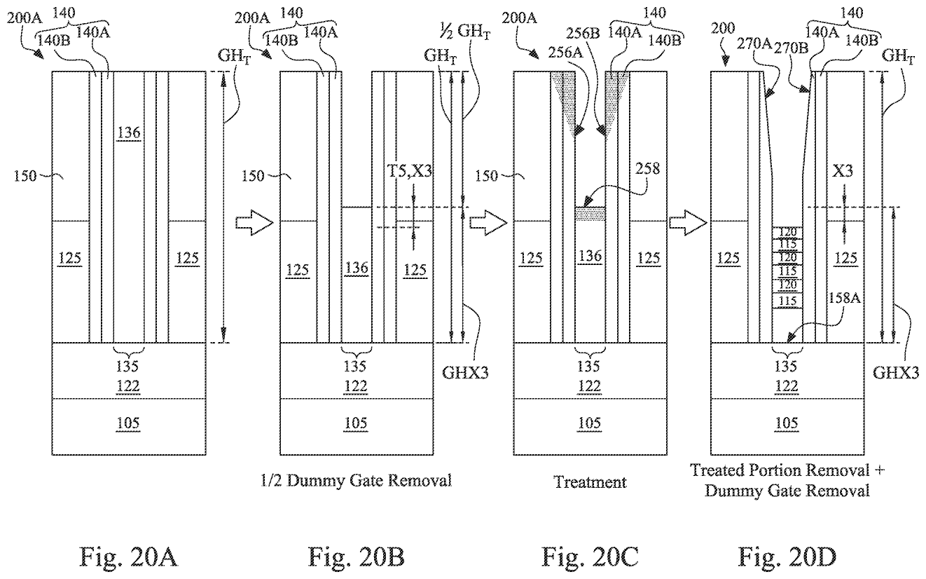

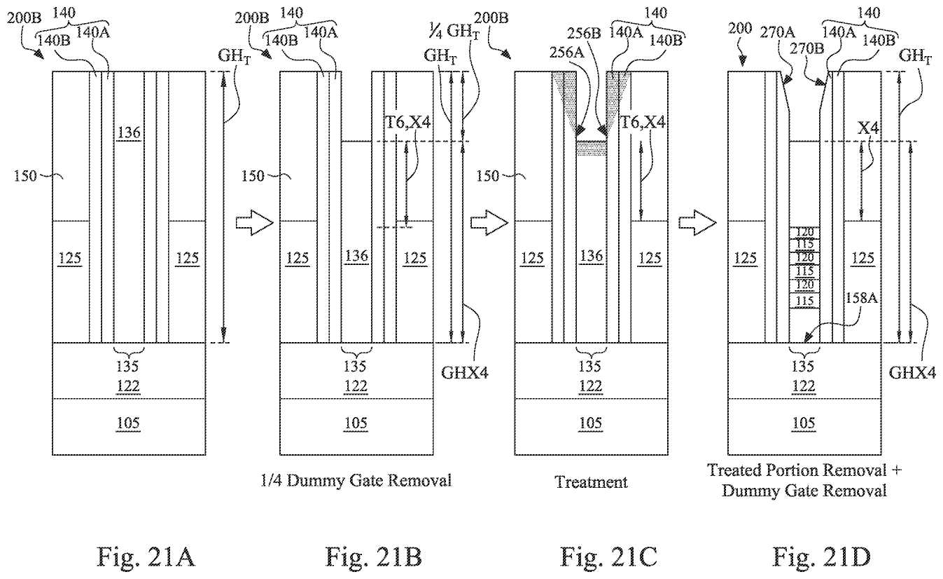

An amount of dummy gate electrode 136 removed and/or an amount of gate spacers 140 exposed to profile modification can be selected to fine-tune tapering of gate spacers 140 and thus a funnel gate profile of gate stack 190. FIGS. 20A-20D are fragmentary cross-sectional views of a device 200A, in portion or entirety, at various fabrication stages when an upper half of gate spacers are exposed for profile modification according to various aspects of the present disclosure. FIGS. 21A-21D are fragmentary cross-sectional views of a device 200B, in portion or entirety, at various fabrication stages when an upper fourth of gate spacers are exposed for profile modification according to various aspects of the present disclosure. Device 200A and device 200B are similar to device 200 described above. Fabrication in FIG. 20A and FIG. 21A is similar to that described with reference to FIGS. 13A-13C, fabrication in FIG. 20B and FIG. 21B is similar to that described with reference to FIGS. 14B-14C, fabrication in FIG. 20C and FIG. 21C is similar to that described with reference to FIGS. 15A-15C, and fabrication in FIG. and FIG. 21D is similar to that described with reference to FIGS. 16A-16C. FIGS. 20A-20D and FIGS. 21A-21D have been simplified for the sake of clarity to better understand the inventive concepts of the present disclosure. Additional features can be added in device 200A and/or device 200B, and some of the features described below can be replaced, modified, or eliminated in other embodiments of device 200A and/or device 200B.

In FIGS. 20A-20D, gate profile modification is achieved by removing an amount (e.g., thickness) of dummy gate electrode 136 that is equal to about ½ total gate height GH_{T}. For example, dummy gate 135 has a gate height GHX3 (e.g., gate height GHX3≈½ total gate height GH_{T}), and dummy gate 135 has a thickness T5 over channel layer 110 (i.e., dummy gate 135 extends a distance X3 above a top of channel layer 110). In such embodiments, treatment process 260 is targeted to portions of gate spacers 140 above gate height GHX3 and tapering of gate spacers 140 begins at gate height GHX3 and/or a distance X3 above channel layer 110. Accordingly, a width of gate stack 190 formed in the gate opening of device 200A will increase from about gate height GHX3 to total gate height GHX_{T}, and a width of gate stack 190 formed in gate opening of device 200A is substantially uniform below about gate height GHX3.

In FIGS. 21A-21D, gate profile modification is achieved by removing an amount (e.g., thickness) of dummy gate electrode 136 that is equal to about ¼ total gate height GH_{T}. For example, dummy gate 135 has a gate height GHX4 (e.g., gate height GHX4≈¾ total gate height GH_{T}), and dummy gate 135 has a thickness T6 over channel layer 110 (i.e., dummy gate 135 extends a distance X4 above a top of channel layer 110). In such embodiments, treatment process 260 is targeted to portions of gate spacers 140 above gate height GHX4 and tapering of gate spacers 140 begins at gate height GHX4 and/or a distance X4 above channel layer 110. Accordingly, a width of gate stack 190 formed in the gate opening of device 200B will increase from about gate height GHX4 to total gate height GHX_{T}, and a width of gate stack 190 formed in gate opening of device 200B is substantially uniform below about gate height GHX4.

When compared to device 200A, since distance X4 is greater than distance X3, a distance above channel layer 110 where tapering of gate spacers 140 begins (and thus where width enlargement of gate stack 190 begins) in device 200B is greater than a distance above channel layer 110 where tapering of gate spacers 140 and/or width enlargement of gate stack 190 begins in device 200A. Further, a length of tapered portions TP of gate spacers 140 along the z-direction in device 200B is less than a length of tapered portions TP of gate spacers 140 along the z-direction in device 200A, and a length of non-tapered portions NTP of gate spacers 140 along the z-direction in device 200B is greater than a length of non-tapered portions NTP of gate spacers 140 in device 200A In some embodiments, a conical-shaped portion of device 200B is smaller than a conical-shaped portion of device 200A (e.g., shorter along the z-direction and/or narrower along the x-direction) and/or a tubular-shaped portion of device 200B is larger than a tubular-shaped portion of device 200A (e.g., longer along the z-direction). In some embodiments, a tapering angle θ of gate spacers 140A in device 200B is greater than a tapering angle θ of gate spacers 140A in device 200A. For example, a tapering angle θ may increase as a distance above channel layer 110 where tapering of gate spacers 140 begins increases.

Devices described herein, such as device 100, device 200, device 200A, and device 200B, may be included in a microprocessor, a memory, and/or other IC device. In some embodiments, a device described herein is a portion of an IC chip, a system on chip (SoC), or portion thereof, that includes various passive and active microelectronic devices, such as resistors, capacitors, inductors, diodes, p-type FETs (PFETs), n-type FETs (NFETs), metal-oxide semiconductor FETs (MOSFETs), complementary metal-oxide semiconductor (CMOS) transistors, bipolar junction transistors (BJTs), laterally diffused MOS (LDMOS) transistors, high voltage transistors, high frequency transistors, other components, or combinations thereof.

The present disclosure provides for many different embodiments. Various methods for forming gate stacks (e.g., high-k/metal gates) with improved profiles (e.g., widths that meet desired critical dimensions and/or having minimal to no seams/voids) and related gate structures are disclosed herein, which may be implemented in a variety of device types. For example, the gate stacks described herein are suitable for planar field-effect transistors (FETs), multigate transistors, such as fin-like FETs (FinFETs), gate-all-around (GAA) transistors, omega-gate (Ω-gate) devices, pi-gate (H-gate) devices, or combinations thereof as well as strained-semiconductor devices, silicon-on-insulator (SOI) devices, partially-depleted SOI devices, fully-depleted SOI devices, other devices, or combinations thereof. The present disclosure contemplates that one of ordinary skill may recognize other IC devices that can benefit from the gate stacks and/or the gate formation techniques described herein.

Gate profile tuning techniques are disclosed herein. The present disclosure contemplates various embodiments of the gate profile tuning techniques. For example, the gate profile modification techniques described with reference to FIGS. 3A-9A, FIGS. 3B-9B, and FIGS. 3C-9C can be implemented for gate structures having gate spacers with multilayer structures and the gate profile modification techniques described with reference to FIGS. 13A-19A, FIGS. 13B-19B, and FIGS. 13C-19C can be implemented for gate structures having spacers with single layer structures. In other words, the present disclosure contemplates embodiments where a dummy gate electrode is partially removed when modifying gate profiles of gate structures having gate spacers with single layer structures (and thus a dummy gate electrode protects the underlying channel layer during gate profile modification) and embodiments where a dummy gate electrode is completely removed when modifying gate profiles of gate structures having gate spacers with multilayer structures (and thus a dummy oxide protects the underlying channel layer during gate profile modification).

An exemplary gate profile tuning method includes forming a gate structure over a channel layer. The gate structure includes a dummy gate and gate spacers disposed along sidewalls of the dummy gate. The method further includes partially removing the dummy gate to form a gate opening that defines a gate profile. The gate profile is then modified by treating portions of the gate spacers and removing the treated portions of the gate spacers. After removing a remainder of the dummy gate to expose the channel layer, a gate stack of the gate structure is formed in the gate opening. The gate stack may have a funnel-shaped profile. In some embodiments, a width of the gate stack above the channel layer is greater than a width of the gate stack below the channel layer.

In some embodiments, treating the portions of the gate spacers includes performing an oxidation process and removing the treated portions of the gate spacers includes removing oxidized portions of the gate spacers. In some embodiments, performing the oxidation process includes exposing the gate spacers to a radical-dominated oxidation, an ion-dominated oxidation, or combinations thereof. In some embodiments, treating the portions of the gate spacers includes tuning a process pressure to control a profile of the treated portions.

In some embodiments, the dummy gate includes a dummy gate electrode and a dummy gate dielectric and partially removing the dummy gate includes removing the dummy gate electrode, wherein a remainder of the dummy gate is the dummy gate dielectric. In some embodiments, the dummy gate includes a dummy gate electrode and a dummy gate dielectric and partially removing the dummy gate includes partially removing the dummy gate electrode, wherein a remainder of the dummy gate is a remainder of the dummy gate electrode and the dummy gate dielectric. In some embodiments, the remainder of the dummy gate extends a distance above the channel layer. In some embodiments, the dummy gate has a total gate height and partially removing the dummy gate includes removing a thickness of the dummy gate that is about ¼ of the total gate height to about ½ of the total gate height.

Another exemplary method includes forming a gate structure over a portion of a semiconductor structure extending from a substrate. The gate structure includes a dummy gate and gate spacers. The method further includes partially removing the dummy gate to expose portions of the gate spacers at least above a top surface of the semiconductor structure. A treatment process is then performed on the gate spacers. The treatment process changes a composition of treated portions of the exposed portions of the gate spacers to enable selective removal of the treated portions. The method further includes removing the treated portions of the exposed portions of the gate spacers and removing a remainder of the dummy gate to enlarge the gate opening. Removing the remainder of the dummy gate exposes the semiconductor structure. A gate stack is formed in and fills the enlarged gate opening. In some embodiments, the semiconductor structure is a semiconductor layer stack and the method further includes performing a channel release process to remove first semiconductor layers of the semiconductor layer stack after removing the remainder of the dummy gate, thereby second semiconductor layers of the semiconductor layer stack over the substrate. In such embodiments, the gate stack is formed after performing the channel release process.

In some embodiments, the treatment process is an O₂ oxygen plasma treatment and the treated portions are silicon oxide portions of the gate spacers. In some embodiments, the gate spacers include silicon, oxygen, carbon, nitrogen, and hydrogen, and the treated portions of the gate spacers include silicon and oxygen. In some embodiments, the gate spacers include inner spacers and outer spacers and the treatment process is performed on the inner spacers. In some embodiments, the method includes tuning the partially removing the dummy gate and the treatment process to provide the enlarged gate opening with a funnel-shaped profile. In some embodiments, a same process is used to remove the treated portions of the exposed portions of the gate spacers and the remainder of the dummy gate. In some embodiments, the gate stack belongs to an input/output device and partially removing the dummy gate includes selectively removing a dummy gate electrode, such that the remainder of the dummy gate includes a dummy gate dielectric. In some embodiments, the gate stack belongs to a logic device and partially removing the dummy gate includes selectively removing a portion of dummy gate electrode, such that the remainder of the dummy gate includes the dummy gate electrode and a dummy gate dielectric. In some embodiments, the gate stack belongs to an input/output device and the dummy gate electrode is partially removed or the gate stack belongs to a logic device and the dummy gate electrode is removed to expose a dummy gate dielectric.

An exemplary device includes a channel layer disposed over a substrate. The channel layer extends between a first source/drain and a second source/drain. A gate stack is disposed between the first source/drain and the second source/drain. The gate stack at least partially surrounds the channel layer and the gate stack has a funnel-shaped profile. A width of the gate stack above a top surface of the channel layer is greater than a width of the gate stack below the channel layer. Gate spacers are disposed along sidewalls of the gate stack. In some embodiments, the gate spacers have tapered portions above the channel layer and non-tapered portions below the channel layer. In some embodiments, the width of the gate stack above the top surface of the channel layer increases from a minimum width at a first distance above the channel layer to a maximum width at a second distance above the channel layer. The second distance is at a top of the gate stack. In some embodiments, the gate spacers include silicon, oxygen, nitrogen, carbon, and hydrogen. In some embodiments, the device is an input/output device. In some embodiments, the device is a logic device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a gate structure over a channel layer, wherein the gate structure includes a dummy gate and gate spacers disposed along sidewalls of the dummy gate;
partially removing the dummy gate to form a gate opening that defines a gate profile;
modifying the gate profile by treating portions of the gate spacers and removing the treated portions of the gate spacers; and
after removing a remainder of the dummy gate to expose the channel layer, forming a gate stack of the gate structure in the gate opening.

2. The method of claim 1, wherein the treating the portions of the gate spacers includes performing an oxidation process and the removing the treated portions of the gate spacers includes removing oxidized portions of the gate spacers.

3. The method of claim 2, wherein the performing the oxidation process includes exposing the gate spacers to a radical-dominated oxidation.

4. The method of claim 2, wherein the performing the oxidation process includes exposing the gate spacers to an ion-dominated oxidation.

5. The method of claim 1, wherein the treating the portions of the gate spacers includes tuning a process pressure to control a profile of the treated portions.

6. The method of claim 1, wherein the dummy gate includes a dummy gate electrode and a dummy gate dielectric and the partially removing the dummy gate includes removing the dummy gate electrode, wherein the remainder of the dummy gate is the dummy gate dielectric.

7. The method of claim 1, wherein the dummy gate includes a dummy gate electrode and a dummy gate dielectric and the partially removing the dummy gate includes partially removing the dummy gate electrode, wherein the remainder of the dummy gate is a remainder of the dummy gate electrode and the dummy gate dielectric.

8. The method of claim 7, wherein the remainder of the dummy gate extends a distance above the channel layer.

9. The method of claim 1, wherein the dummy gate has a total gate height and the partially removing the dummy gate includes removing a thickness of the dummy gate that is about ¼ of the total gate height to about ½ of the total gate height.

10. A method comprising:
forming a gate structure over a portion of a semiconductor structure extending from a substrate, wherein the gate structure includes a dummy gate and gate spacers;
partially removing the dummy gate to form a gate opening that exposes portions of the gate spacers at least above a top surface of the semiconductor structure;
performing a treatment process on the gate spacers, wherein the treatment process changes a composition of treated portions of the exposed portions of the gate spacers to enable selective removal of the treated portions of the exposed portions of the gate spacers;
removing the treated portions of the exposed portions of the gate spacers and removing a remainder of the dummy gate to enlarge the gate opening, wherein the removing the remainder of the dummy gate exposes the semiconductor structure; and
forming a gate stack that fills the enlarged gate opening.

11. The method of claim 10, wherein the treatment process is an O₂ oxygen plasma treatment and the treated portions are silicon oxide portions of the gate spacers.

12. The method of claim 10, wherein the gate spacers include silicon, oxygen, carbon, nitrogen, and hydrogen, and the treated portions of the gate spacers include silicon and oxygen.

13. The method of claim 10, wherein the gate spacers include inner spacers and outer spacers and the treatment process is performed on the inner spacers.

14. The method of claim 10, wherein the partially removing the dummy gate and the treatment process are tuned to provide the enlarged gate opening with a funnel-shaped profile.

15. The method of claim 10, wherein a same process is used to remove the treated portions of the exposed portions of the gate spacers and the remainder of the dummy gate.

16. The method of claim 10, wherein the semiconductor structure is a semiconductor layer stack and the method further includes:
performing a channel release process to remove first semiconductor layers of the semiconductor layer stack after removing the remainder of the dummy gate, thereby second semiconductor layers of the semiconductor layer stack over the substrate; and
forming the gate stack after performing the channel release process.

17. A device comprising:
a channel layer disposed over a substrate, wherein the channel layer extends between a first source/drain and a second source/drain;
a gate stack disposed between the first source/drain and the second source/drain, wherein the gate stack at least partially surrounds the channel layer and the gate stack has a funnel-shaped profile, and further wherein a width of the gate stack above a top surface of the channel layer is greater than a width of the gate stack below the channel layer; and
gate spacers disposed along sidewalls of the gate stack.

18. The device of claim 17, wherein the gate spacers have tapered portions above the channel layer and non-tapered portions below the channel layer.

19. The device of claim 17, wherein the width of the gate stack above the top surface of the channel layer increases from a minimum width at a first distance above the channel layer to a maximum width at a second distance above the channel layer, wherein the second distance is at a top of the gate stack.

20. The device of claim 17, wherein the gate spacers include silicon, oxygen, nitrogen, carbon, and hydrogen.
